(19) United States
(12) Patent Application Publication
(10) Pub. No.: US 2021/0028303 A1
(43) Pub. Date: Jan. 28, 2021

(54) SEMICONDUCTOR DEVICE AND METHOD FOR FABRICATING THE SAME

(71) Applicant: Panasonic Intellectual Property Management Co., Ltd., Osaka (JP)

(72) Inventors: Asamira SUZUKI, Osaka (JP); Hidetoshi ISHIDA, Osaka (JP)

(21) Appl. No.: 16/982,210

(22) PCT Filed: Mar. 22, 2019
(86) PCT No.: PCT/JP2019/012045

§ 371 Date: Sep. 18, 2020

(30) Foreign Application Priority Data
Mar. 29, 2018 (JP) 2018-063913
Mar. 29, 2018 (JP) 2018-063914

(51) Int. Cl. H01L 29/778; H01L 29/20; H01L 21/02; H01L 29/66

(52) U.S. Cl. CPC H01L 29/7786; H01L 29/66431; H01L 21/02293; H01L 29/2003

(57) ABSTRACT

A plurality of semiconductor portions are arranged in a first direction to be spaced apart from each other. A heterojunction of each of the plurality of semiconductor portions extends in a second direction perpendicular to a first direction aligned with a c-axis of a first nitride semiconductor portion. Each of a plurality of first electrodes overlaps with an associated one of the plurality of semiconductor portions in a third direction perpendicular to both of the first direction and the second direction, and is directly electrically connected to the heterojunction of the associated semiconductor portion. Each of the plurality of second electrodes is located, with respect to an associated one of the plurality of semiconductor portions, opposite in the third direction from one of the plurality of first electrodes that overlaps with the associated semiconductor portion, and is directly electrically connected to the heterojunction of the associated semiconductor portion.

### TECHNICAL FIELD

The present disclosure generally relates to a semiconductor device and a method for fabricating the same, and more particularly relates to a semiconductor device having a heterojunction and a method for fabricating such a semiconductor device.

### BACKGROUND ART

A vertical semiconductor device, of which the source and drain regions are arranged to be separated vertically, has been known as a type of semiconductor device (see, for example, Patent Literature 1)

The semiconductor device of Patent Literature 1 includes a drain electrode, a drain region, a drift portion, a gate portion, a source region, and a source electrode.

In the semiconductor device of Patent Literature 1, the drain region is provided on the drain electrode. The drift portion is provided on the drain region. The gate portion is provided on a part of the drift portion. The source region is arranged on another part of the drift portion.

The drain region is made of gallium nitride. The drift portion includes a first semiconductor region of aluminum gallium nitride and a second semiconductor region of gallium nitride. The first semiconductor region and the second semiconductor region extend in a direction in which the drain region and the gate portion are connected together. The first semiconductor region and the second semiconductor region are directly in contact with each other. The first semiconductor region and the second semiconductor region form a first heterojunction. The first heterojunction is formed on a c-plane. The first semiconductor region and the second semiconductor region are arranged repeatedly in one direction in a plan view.

The gate portion includes a third semiconductor region of gallium nitride and a fourth semiconductor region of aluminum gallium nitride. The third semiconductor region and the fourth semiconductor region extend perpendicularly to the direction in which the drain region and the gate portion are connected together. The third semiconductor region and the fourth semiconductor region form a second heterojunction. The second heterojunction is formed on an a-plane.

The source region is made of gallium nitride and aluminum gallium nitride. The source region is electrically connected to the source electrode.

Meanwhile, a nitride semiconductor device such as a field-effect transistor using a GaN-based compound semiconductor has also been known as another type of semiconductor device (see, for example, Patent Literature 2).

The nitride semiconductor device of Patent Literature 2 includes: a substrate of sapphire, of which the principal surface has (0001) crystallographic orientation; a first semiconductor layer of undoped GaN; a second semiconductor layer of undoped Al_{0.15}Ga_{0.85}N formed on the first semiconductor layer; a control region formed locally on the second semiconductor layer; a gate electrode formed on the control region; and a source electrode and a drain electrode formed on the second semiconductor layer. The control region is made up of a control layer and a contact layer. The control layer is made of p-type Al_{0.15}Ga_{0.85}N which is formed on the second semiconductor layer. The contact layer is made of high-concentration p-type GaN which is formed on the control layer.

Semiconductor devices such as transistors and diodes suitably cause as little ON-state loss as possible.

### CITATION LIST

### Patent Literature

Patent Literature 1: JP 2008-258514 A

Patent Literature 2: JP 2007-201093 A

### SUMMARY OF INVENTION

An object of the present disclosure is to provide a semiconductor device contributing to reducing the electrical resistance and a method for fabricating such a semiconductor device.

A semiconductor device according to an aspect of the present disclosure includes a plurality of semiconductor portions, a plurality of first electrodes, a plurality of second electrodes, a first common electrode, and a second common electrode. The plurality of semiconductor portions are arranged in a first direction to be spaced apart from each other. Each of the plurality of semiconductor portions has a heterojunction between a first nitride semiconductor portion and a second nitride semiconductor portion having a larger bandgap than the first nitride semiconductor portion. The heterojunction of each of the plurality of semiconductor portions extends in a second direction perpendicular to a first direction aligned with a c-axis of the first nitride semiconductor portion. Each of the plurality of first electrodes overlaps with an associated one of the plurality of semiconductor portions in a third direction perpendicular to both of the first direction and the second direction. Each of the plurality of first electrodes is directly electrically connected to the heterojunction of the associated semiconductor portion. Each of the plurality of second electrodes forms a pair of first and second electrodes with one of the plurality of first electrodes and is located, with respect to an associated one of the plurality of semiconductor portions, opposite in the third direction from the one of the plurality of first electrodes that overlaps with the associated semiconductor portion such that the associated semiconductor portion is sandwiched in the third direction between the pair of first and second electrodes. Each of the plurality of second electrodes is directly electrically connected to the heterojunction of the associated semiconductor portion. The plurality of first electrodes are electrically connected in common to the first common electrode. The plurality of second electrodes are electrically connected in common to the second common electrode.

A method for fabricating a semiconductor device according to another aspect of the present disclosure is a method for fabricating a semiconductor device according to still another aspect of the present disclosure. The semiconductor device according to still another aspect of the present disclosure includes a plurality of semiconductor portions, a plurality of first electrodes, a plurality of second electrodes, a first common electrode, and a second common electrode. The plurality of semiconductor portions are arranged in a first direction to be spaced apart from each other. Each of the plurality of semiconductor portions has a heterojunction between a first nitride semiconductor portion and a second nitride semiconductor portion having a larger bandgap than the first nitride semiconductor portion. The heterojunction of each of the plurality of semiconductor portions extends in a second direction perpendicular to a first direction aligned with a c-axis of the first nitride semiconductor portion. Each of the plurality of first electrodes overlaps with an associated one of the plurality of semiconductor portions in a third direction perpendicular to both of the first direction and the second direction Each of the plurality of first electrodes is directly electrically connected to the heterojunction of the associated semiconductor portion. Each of the plurality of second electrodes forms a pair of first and second electrodes with one of the plurality of first electrodes and is located, with respect to an associated one of the plurality of semiconductor portions, opposite in the third direction from the one of the plurality of first electrodes that overlaps with the associated semiconductor portion such that the associated semiconductor portion is sandwiched in the third direction between the pair of first and second electrodes. Each of the plurality of second electrodes is directly electrically connected to the heterojunction of the associated semiconductor portion. The plurality of first electrodes are electrically connected in common to the first common electrode. The plurality of second electrodes are electrically connected in common to the second common electrode. The semiconductor device according to still another aspect further includes a substrate. The substrate has a first surface and a second surface located opposite from each other in the third direction. The plurality of second electrodes are arranged on the first surface of the substrate. The substrate is a nitride semiconductor substrate. The first surface is a crystallographic plane aligned with a c-axis of the nitride semiconductor substrate. Each of the plurality of second electrodes extends linearly in the second direction. The plurality of second electrodes are arranged on the first surface of the substrate to be spaced apart from each other in the first direction. The method for fabricating a semiconductor device according to another aspect of the present disclosure includes a mask portion forming step, a first epitaxial growth step, and a second epitaxial growth step. The mask portion forming step includes forming a plurality of mask portions each extending linearly on the first surface of the substrate. The plurality of mask portions are arranged along a c-axis of the substrate. The first epitaxial growth step includes forming a plurality of the first nitride semiconductor portions by epitaxial lateral overgrowth (ELO). Each of the plurality of the first nitride semiconductor portions covers a region between two adjacent ones of the plurality of mask portions on the first surface of the substrate and respective surface portions of the two adjacent mask portions. The second epitaxial growth step includes epitaxially growing a plurality of the second nitride semiconductor portions on an associated one of the plurality of the first nitride semiconductor portions.

A semiconductor device according to yet another aspect of the present disclosure includes a nitride semiconductor substrate, a plurality of insulator portions, a plurality of semiconductor portions, a plurality of first electrodes, a plurality of second electrodes, a first common electrode, and a second common electrode. The nitride semiconductor substrate has a first surface and a second surface located opposite from each other in a thickness direction. The first surface of the nitride semiconductor substrate is a crystallographic plane aligned with a c-axis. Each of the plurality of insulator portions is elongated linearly in a second direction perpendicular to both the thickness direction and a first direction aligned with the c-axis of the nitride semiconductor substrate. The plurality of insulator portions are arranged side by side in the first direction on the first surface of the nitride semiconductor substrate. The plurality of semiconductor portions are arranged in the first direction to be spaced apart from each other. Each of the plurality of semiconductor portions includes a first nitride semiconductor portion and a second nitride semiconductor portion. The first nitride semiconductor portion is formed on a region between two adjacent ones of the plurality of insulator portions on the first surface of the nitride semiconductor substrate and extends over the two adjacent insulator portions. The second nitride semiconductor portion is directly formed on one surface, aligned with a +c plane, out of two surfaces intersecting with the first direction in the first nitride semiconductor portion. Each of the plurality of first electrodes is electrically connected to a heterojunction between the first nitride semiconductor portion and the second nitride semiconductor portion of an associated one of the plurality of semiconductor portions. Each of the plurality of second electrodes is electrically connected to the heterojunction between the first nitride semiconductor portion and the second nitride semiconductor portion of an associated one of the plurality of semiconductor portions. Each of the plurality of second electrodes is spaced in the second direction from an associated one of the plurality of first electrodes. The plurality of first electrodes are electrically connected in common to the first common electrode. The plurality of second electrodes are electrically connected in common to the second common electrode.

A method for fabricating a semiconductor device according to yet another aspect of the present disclosure is a method for fabricating the semiconductor device described above. The method includes an insulator portion forming step, a first epitaxial growth step, and a second epitaxial growth step. The insulator portion forming step includes forming the plurality of insulator portions on the first surface of the nitride semiconductor substrate. The first epitaxial growth step includes forming the plurality of the first nitride semiconductor portions by epitaxial lateral overgrowth (ELO). The second epitaxial growth step includes epitaxially growing the second nitride semiconductor portion on each of the plurality of the first nitride semiconductor portions.

### BRIEF DESCRIPTION OF DRAWINGS

FIG. 1A is a plan view of a semiconductor device according to a first embodiment;

FIG. 1B is a cross-sectional view of the semiconductor device taken along the plane X-X shown in FIG. 1A;

FIG. 2 is a graph showing a relationship between the breakdown voltage and ON-state resistance of the semiconductor device;

FIG. 3 is a graph showing a relationship between a taper angle on the surface of a second nitride semiconductor portion of the semiconductor device and the concentration of a two-dimensional electron gas of the semiconductor portion;

FIG. 4 is a graph showing how the relationship between the taper angle on the surface of the second nitride semiconductor portion of the semiconductor device and the concentration of the two-dimensional electron gas of the semiconductor portion varies with the composition ratio of the second nitride semiconductor portion;

FIGS. 5A-5C are cross-sectional views illustrating major process steps of a method for fabricating the semiconductor device;

FIGS. 6A-6C are plan views illustrating major process steps of the method for fabricating the semiconductor device;

FIGS. 7A-7D are cross-sectional views illustrating major process steps of the method for fabricating the semiconductor device;

FIGS. 8A-8D are plan views illustrating major process steps of the method for fabricating the semiconductor device;

FIG. 9A is a plan view of a semiconductor device according to a second embodiment;

FIG. 9B is a cross-sectional view of the semiconductor device taken along the plane X-X shown in FIG. 9A;

FIG. 10 is a graph showing a relationship between the breakdown voltage and ON-state resistance of the semiconductor device;

FIGS. 11A-11C are cross-sectional views illustrating major process steps of a method for fabricating the semiconductor device;

FIGS. 12A-12C are plan views illustrating major process steps of the method for fabricating the semiconductor device;

FIGS. 13A-13C are cross-sectional views illustrating major process steps of the method for fabricating the semiconductor device; and

FIGS. 14A-14C are plan views illustrating major process steps of the method for fabricating the semiconductor device.

### DESCRIPTION OF EMBODIMENTS

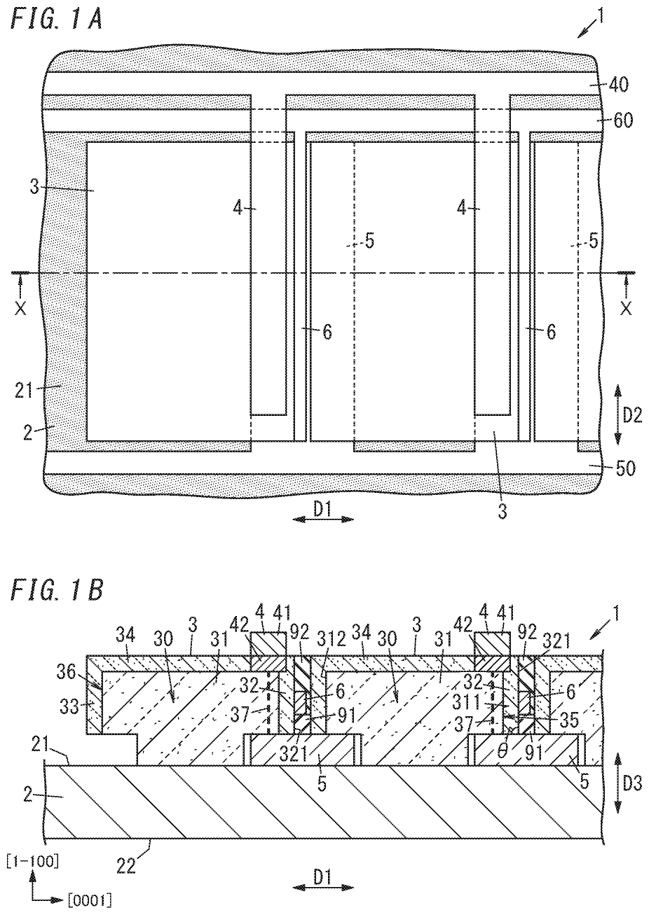

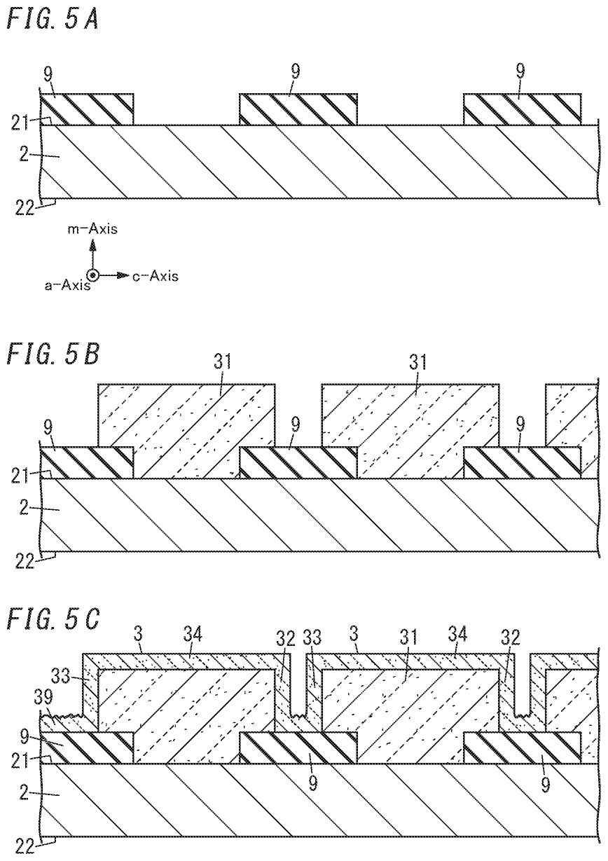

Note that FIG. 1A, FIG. 1B, FIGS. 5A-5C, FIGS. 6A-6C, FIGS. 7A-7D, FIGS. 8A-8D, FIG. 9A, FIG. 9B, FIGS. 11A-11C, FIGS. 12A-12C, FIGS. 13A-13C, and FIGS. 14A-14C to be referred to in the following description of embodiments are all schematic representations. That is to say, the ratio of the dimensions (including thicknesses) of respective constituent elements illustrated on these drawings does not always reflect their actual dimensional ratio.

### First Embodiment

A semiconductor device 1 according to a first embodiment will be described with reference to FIGS. 1A and 1B.

The semiconductor device 1 includes a plurality of semiconductor portions 3, a plurality of first electrodes 4, a plurality of second electrodes 5, a first common electrode 40, and a second common electrode 50. The plurality of semiconductor portions 3 are arranged in a first direction D1 to be spaced apart from each other. Each of the plurality of semiconductor portions 3 has a heterojunction 35 between a first nitride semiconductor portion 31 and a second nitride semiconductor portion 32 having a larger bandgap than the first nitride semiconductor portion 31. The heterojunction 35 of each of the plurality of semiconductor portions 3 extends in a second direction D2 perpendicular to the first direction D1 aligned with a c-axis of the first nitride semiconductor portion 31. Each of the plurality of first electrodes 4 overlaps with an associated one of the plurality of semiconductor portions 3 in a third direction D3 perpendicular to both of the first direction D1 and the second direction D2. Each of the plurality of first electrodes 4 is directly electrically connected to the heterojunction 35 of the associated semiconductor portion 3. Each of the plurality of second electrodes 5 is located, with respect to an associated one of the plurality of semiconductor portions 3, opposite in the third direction D3 from one of the plurality of first electrodes 4 that overlaps with the associated semiconductor portion 3 such that the associated semiconductor portion 3 is sandwiched in the third direction D3 between the first electrode 4 and the second electrode 5. Each of the plurality of second electrodes 5 is directly electrically connected to the heterojunction 35 of the associated semiconductor portion 3. The plurality of first electrodes 4 are electrically connected in common to the first common electrode 40. The plurality of second electrodes 5 are electrically connected in common to the second common electrode 50. In FIG. 1A, the substrate 2 is hatched with dots. Note that this hatching does not indicate a cross section but is just provided there to clarify the relationship between the substrate 2 and the other constituent elements (including the respective semiconductor portions 3, the respective first electrodes 4, the respective second electrodes 5, the first common electrode 40, and the second common electrode 50).

The semiconductor device 1 further includes a substrate 2. The substrate 2 has a first surface 21, which is located in the third direction D3 closer to the plurality of semiconductor portions 3, and a second surface 22, which is located in the third direction D3 more distant from the plurality of semiconductor portions 3. The plurality of second electrodes 5 are arranged on the first surface 21 of the substrate 2. Each of the plurality of second electrodes 5 extends linearly in the second direction D2. The plurality of second electrodes 5 are arranged on the first surface 21 of the substrate 2 to be spaced apart from each other in the first direction D1.

The semiconductor device 1 further includes a plurality of gate electrodes 6. Each of the plurality of gate electrodes 6 faces, in the first direction D1, the second nitride semiconductor portion 32 of an associated one of the plurality of semiconductor portions 3.

As shown in FIG. 1B, the semiconductor device 1 further includes a plurality of first insulating layers 91, each of which is interposed in the third direction D3 between an associated one of the gate electrodes 6 and an associated one of the second electrodes 5. Each of the first insulating layers 91 has electrical insulation properties. As shown in FIG. 1B, the semiconductor device 1 further includes a plurality of second insulating layers 92, each of which is interposed between two adjacent ones of the plurality of semiconductor portions 3. Each of the second insulating layers 92 is formed in the third direction D3 over an associated one of the first insulating layers 91 to cover an associated one of the gate electrodes 6. The second insulating layers 92 have electrical insulation properties. Note that in FIG. 1A, illustration of the first insulating layers 91 and the second insulating layers 92 is omitted.

A semiconductor device 1 according to the first embodiment is implemented as a field-effect transistor chip. In the semiconductor device 1 according to this embodiment, the plurality of first electrodes 4 constitutes a plurality of source electrodes and the plurality of second electrodes 5 constitutes a plurality of drain electrodes. In the following description, the plurality of first electrodes 4 and the plurality of second electrodes 5 will be hereinafter sometimes referred to as “a plurality of source electrodes 4” and “a plurality of drain electrodes 5” for the sake of convenience.

Next, the respective constituent elements of the semiconductor device 1 will be described in further detail.

When viewed in plan in the thickness direction (third direction D3) defined with respect to the semiconductor device 1, the semiconductor device 1 may have a square outer peripheral shape, for example. When viewed in plan in the thickness direction defined with respect to the semiconductor device 1, the semiconductor device 1 may have a chip size of 5 mm square (5 mm×5 mm), for example. Note that this numerical value is only an example and should not be construed as limiting. In addition, the semiconductor device 1 does not have to have a square outer peripheral shape, either, but may have a rectangular outer peripheral shape as well.

The substrate 2 supports the semiconductor portions 3 thereon. The substrate 2 may be a nitride semiconductor substrate, for example. Therefore, the substrate 2 has a hexagonal crystal structure. The first direction D1 is defined along a c-axis of the substrate 2 (which may be parallel to the c-axis of the substrate 2, for example). The c-axis of the substrate 2 points to the right in each of FIGS. 1A and 1B. At the lower left corner of FIG. 1B, shown are a crystallographic axis [0001] indicating the c-axis of the substrate 2 and a crystallographic axis [1-100] indicating the m-axis thereof. The first surface 21 of the substrate 2 is a crystallographic plane aligned with the c-axis of the nitride semiconductor substrate. The substrate 2 may be a single-crystal GaN substrate, for example. The single crystal GaN substrate may be a semi-insulating GaN substrate, for example.

As described above, the substrate 2 has the first surface 21 and the second surface 22, which are located opposite from each other in the thickness direction (third direction D3) defined for the substrate 2. In this case, the first surface 21 of the substrate 2 is an m-plane, which may be a (1-100) plane, for example. As used herein, the negative sign “−” added to a Miller index representing a crystallographic plane orientation indicates the inversion of the index following the negative sign. The (1-100) plane is a crystallographic plane represented by four Miller indices enclosed in parentheses.

The first surface 21 of the substrate 2 may be a nonpolar plane aligned with the c-axis and does not have to be an m-plane but may be an a-plane as well. The a-plane may be a (11-20) plane, for example. Alternatively, the first surface 21 of the substrate 2 may also be a crystallographic plane, of which an off-axis angle with respect to an m-plane (hereinafter referred to as a “first off-axis angle”) is greater than 0 degrees and equal to or less than 5 degrees. As used herein, the “first off-axis angle” indicates a tilt angle of the first surface 21 with respect to the m-plane. Thus, if the first off-axis angle is 0 degrees, then the first surface 21 is an m-plane. Likewise, the first surface 21 of the substrate 2 may also be a crystallographic plane, of which an off-axis angle with respect to an a-plane (hereinafter referred to as a “second off-axis angle”) is greater than 0 degrees and equal to or less than 5 degrees. As used herein, the “second off-axis angle” indicates a tilt angle of the first surface 21 with respect to the a-plane. Thus, if the second off-axis angle is 0 degrees, then the first surface 21 is an a-plane. The substrate 2 may have a thickness falling within the range from 100 μm to 700 μm, for example.

The plurality of semiconductor portions 3 are provided on the first surface 21 of the substrate 2. Each of the plurality of semiconductor portions 3 includes a first nitride semiconductor portion 31 and a second nitride semiconductor portion 32, of which the magnitudes of bandgaps are different from each other. The composition of the second nitride semiconductor portion 32 is different from that of the first nitride semiconductor portion 31. In each of the plurality of semiconductor portions 3, the first nitride semiconductor portion 31 and the second nitride semiconductor portion 32 are arranged side by side in the first direction D1. Also, each of the plurality of semiconductor portions 3 further includes a third nitride semiconductor portion 33, of which the magnitude of bandgap is different from that of the first nitride semiconductor portion 31. The third nitride semiconductor portion 33 is located opposite in the first direction D1 from the second nitride semiconductor portion 32 with respect to the first nitride semiconductor portion 31.

Each of the plurality of semiconductor portions 3 further includes a fourth nitride semiconductor portion 34, of which the magnitude of bandgap is different from that of the first nitride semiconductor portion 31. Each fourth nitride semiconductor portion 34 is located between an end portion, opposite from the substrate 2, of the second nitride semiconductor portion 32 and an end portion, opposite from the substrate 2, of the third nitride semiconductor portion 33 in the associated semiconductor portion 3.

In each of the plurality of semiconductor portions 3, when measured in the first direction D1, the respective thicknesses of the second nitride semiconductor portion 32 and the third nitride semiconductor portion 33 are smaller than the thickness of the first nitride semiconductor portion 31. In addition, in each of the plurality of semiconductor portions 3, when measured in the thickness direction (third direction D3) defined for the substrate 2, the thickness of the fourth nitride semiconductor portion 34 is smaller than the thickness of the first nitride semiconductor portion 31.

As measured in the thickness direction (third direction D3) defined for the substrate 2, the thickness of the first nitride semiconductor portion 31 may be 7.5 μm, for example. However, this is only an example of the present disclosure and should not be construed as limiting. Rather the thickness of the first nitride semiconductor portion 31 suitably falls within the range from 5 μm to 30 μm. Also, the thickness of the first nitride semiconductor portion 31 as measured in the first direction D1 may be 4 μm, for example. Furthermore, the respective thicknesses of the second nitride semiconductor portion 32 and the third nitride semiconductor portion 33 as measured in the first direction D1 may be 20 nm, for example. The thickness of the fourth nitride semiconductor portion 34 as measured in the thickness direction (third direction D3) defined for the substrate 2 may be 20 nm, for example.

The first nitride semiconductor portion 31 may be made up of undoped GaN crystals. Each of the second nitride semiconductor portion 32, the third nitride semiconductor portion 33, and the fourth nitride semiconductor portion 34 may be made up of undoped AlGaN crystals. Each of the first nitride semiconductor portion 31, the second nitride semiconductor portion 32, the third nitride semiconductor portion 33, and the fourth nitride semiconductor portion 34 may be an epitaxial layer. In each of the plurality of semiconductor portions 3, the second nitride semiconductor portion 32, the third nitride semiconductor portion 33, and the fourth nitride semiconductor portion 34 may have the same Al composition ratio (of 0.25, for example). However, this is only an example and should not be construed as limiting. Alternatively, the second, third, and fourth nitride semiconductor portions 32, 33, and 34 may have different Al composition ratios. In this specification, the composition ratio may be a value obtained by composition analysis according to energy dispersive X-ray spectroscopy (EDX). When their magnitudes are discussed, the composition ratios do not have to be values obtained by the EDX but may also be values obtained by composition analysis according to Auger electron spectroscopy, for example.

Each of the plurality of semiconductor portions 3 has the heterojunction 35 defining a junction between the first nitride semiconductor portion 31 and the second nitride semiconductor portion 32 (hereinafter referred to as a “first heterojunction 35”). The first heterojunction 35 intersects (e.g., at right angles in this embodiment) with the first direction D1 aligned with the first surface 21 of the substrate 2. Each of the plurality of semiconductor portions 3 also has a heterojunction 36 defining a junction between the first nitride semiconductor portion 31 and the third nitride semiconductor portion 33 (hereinafter referred to as a “second heterojunction 36”). The second heterojunction 36 intersects (e.g., at right angles in this embodiment) with the first direction D1 aligned with the first surface 21 of the substrate 2. In each of the plurality of semiconductor portions 3, the first heterojunction 35 and the second heterojunction 36 may extend in the second direction D2 perpendicular to the first direction D1. However, the first heterojunction 35 and the second heterojunction 36 do not always intersect at right angles with the first direction D1 (i.e., the angle formed between each of the first heterojunction 35 and the second heterojunction 36 and the first direction D1 is not always 90 degrees). In other words, the angle (interior angle) formed between the first heterojunction 35 and a surface, parallel to the first surface 21 of the substrate 2, of one of the plurality of second electrodes 5 in the semiconductor portion 3 does not have to be 90 degrees but may fall within the range from 70 degrees to 100 degrees. The angle (interior angle) formed between the second heterojunction 36 and the first surface 21 of the substrate 2 does not have to be 90 degrees but may fall within the range from 70 degrees to 100 degrees.

The first nitride semiconductor portion 31 is formed directly on the first surface 21 of the substrate 2. The first nitride semiconductor portion 31 has a T-shape when viewed in the second direction D2. More specifically, when viewed in the second direction D2, a portion, located closer in the third direction D3 to the first surface 21 of the substrate 2, of the first nitride semiconductor portion 31 has a narrower width in the first direction D1 than another portion, located more distant from the first surface 21 of the substrate 2, of the first nitride semiconductor portion 31.

The first nitride semiconductor portion 31 has a first surface 311 and a second surface 312, which are located opposite from each other in the first direction D1. In other words, the first nitride semiconductor portion 31 has a first surface 311 and a second surface 312, which intersect with the first direction D1 and which are spaced apart from each other in the first direction D1. The first surface 311 is a Group III polar plane (a Ga polar plane in this embodiment) of the first nitride semiconductor portion 31. The Ga polar plane (+c plane) is a (0001) plane. The first surface 311 does not have to be a Group III polar plane but may also be a crystallographic plane forming a tilt angle of approximately 1 to 30 degrees with respect to the Group III polar plane. The second surface 312 is a Group V polar plane (an N polar plane in this embodiment) of the first nitride semiconductor portion 31. The N polar plane (−c plane) is a (000-1) plane. The second surface 312 does not have to be a Group V polar plane but may also be a crystallographic plane forming a tilt angle of approximately 1 to 30 degrees with respect to the Group V polar plane.

In each of the plurality of semiconductor portions 3, the first heterojunction 35 is formed to include the first surface 311 of the first nitride semiconductor portion 31. In addition, in each of the plurality of semiconductor portions 3, the second heterojunction 36 is formed to include the second surface 312 of the first nitride semiconductor portion 31.

In each of the plurality of semiconductor portions 3, in the vicinity of the first heterojunction 35 intersecting with the first direction D1, a two-dimensional electron gas 37 has been generated by spontaneous polarization and piezoelectric polarization of a nitride semiconductor (e.g., undoped AlGaN crystals that form the second nitride semiconductor portion 32). In other words, in each of the plurality of semiconductor portions 3, the first heterojunction 35 generates the two-dimensional electron gas 37. A region including the two-dimensional electron gas 37 (hereinafter referred to as a “two-dimensional electron gas layer”) may function as an n-channel layer (electron conduction layer). In addition, in each of the plurality of semiconductor portions 3, in the vicinity of the second heterojunction 36 intersecting with the first direction D1, a two-dimensional hole gas has been generated by spontaneous polarization and piezoelectric polarization of a nitride semiconductor (e.g., undoped AlGaN crystals that form the third nitride semiconductor portion 33). In other words, in each of the plurality of semiconductor portions 3, the second heterojunction 36 generates the two-dimensional hole gas. A region including the two-dimensional hole gas (hereinafter referred to as a “two-dimensional hole gas layer”) may function as a p-channel layer (hole conduction layer).

The semiconductor device 1 includes a plurality of (e.g., 1,000) double heterostructures 30, which are arranged side by side in the first direction D1 to be separated from each other. In each of the plurality of double heterostructures 30, the third nitride semiconductor portion 33, the first nitride semiconductor portion 31, and the second nitride semiconductor portion 32 are arranged side by side in this order in the first direction D1.

Each of the double heterostructures 30 has the first heterojunction 35 and the second heterojunction 36 described above. Thus, the semiconductor device 1 includes a plurality of (e.g., 1,000) first heterojunctions 35 and a plurality of (e.g., 1,000) second heterojunctions 36. In this embodiment, in the semiconductor device 1, the plurality of first heterojunctions 35 extend parallel to each other, and the plurality of second heterojunctions 36 also extend parallel to each other. In this semiconductor device 1, the plurality of first heterojunctions 35 are arranged in the first direction D1 at generally regular intervals. Also, in this semiconductor device 1, the interval between the respective surfaces 321 of the second nitride semiconductor portions 32 of the two semiconductor portions 3 adjacent to each other in the first direction D1 (i.e., a pitch between a plurality of semiconductor portions 3) may be 7.5 μm, for example.

In addition, in the semiconductor device 1, the plurality of semiconductor portions 3 correspond one to one to the plurality of first electrodes 4. Each of the plurality of first electrodes 4 extends linearly in the second direction D2. The plurality of first electrodes 4 are arranged in the first direction D1 to be spaced apart from each other. In the semiconductor device 1, each of the plurality of first electrodes 4 is directly electrically connected to the heterojunction 35 of its associated semiconductor portion 3. As used herein, to be “electrically connected to” means making ohmic contact with. Also, as used herein, to be “directly electrically connected to the heterojunction 35 of its associated semiconductor portion 3” means being electrically connected to the heterojunction 35 of the associated semiconductor portion 3 with no semiconductor layer interposed between the first electrode 4 and the first nitride semiconductor portion 31 and the second nitride semiconductor portion 32. In this embodiment, the first electrode 4 includes an alloy portion 42 to make ohmic contact with the heterojunction 35 of the semiconductor portion 3 and a metallic portion 41 on the alloy portion 42. In the semiconductor device 1, the metallic portion 41 of the first electrode 4 may include Ti and Al, for example, and the alloy portion 42 may include Al, Ti, and Ga, for example. The alloy portion 42 is formed to cover a part of the first nitride semiconductor portion 31 and a part of the second nitride semiconductor portion 32. Thus, the alloy portion 42 overlaps with the first heterojunction 35 in the third direction D3.

In addition, in the semiconductor device 1, the plurality of semiconductor portions 3 correspond one to one to the plurality of second electrodes 5. Each of the plurality of second electrodes 5 extends linearly in the second direction D2. The plurality of second electrodes 5 are arranged in the first direction D1 to be spaced apart from each other. Each of the plurality of second electrodes 5 is located opposite in the third direction D3 from the first electrode 4 with respect to an associated one of the plurality of semiconductor portions 3 such that the associated semiconductor portion 3 is sandwiched between the first electrode 4 and the second electrode 5, and is directly electrically connected to the heterojunction 35 of its associated semiconductor portion 3. As used herein, to be “electrically connected to” means making ohmic contact with. Also, as used herein, to be “directly electrically connected to the heterojunction 35 of its associated semiconductor portion 3” means being electrically connected to the heterojunction 35 of the associated semiconductor portion 3 with no semiconductor layer interposed between the second electrode 5 and the first nitride semiconductor portion 31 or the second nitride semiconductor portion 32. In the semiconductor device 1, the plurality of first electrodes 4 correspond one to one to the plurality of second electrodes 5, and each corresponding pair of first and second electrodes 4 and 5 face each other in the third direction D3 with the semiconductor portion 3 sandwiched between them. That is to say, in the semiconductor device 1, each corresponding pair of first and second electrodes 4 and 5 are separate from each other in the third direction D3. In the semiconductor device 1, only the semiconductor portion 3 is interposed in the third direction D3 between each corresponding pair of first and second electrodes 4 and 5. Furthermore, in the semiconductor device 1, each of the plurality of second electrodes 5 is arranged to overlap with two semiconductor portions 3 that are adjacent to each other in the first direction D1. Each of the plurality of second electrodes 5 is directly electrically connected to the first heterojunction 35 of one of the two semiconductor portions 3 that are adjacent to each other in the first direction D1. The plurality of second electrodes 5 are arranged on the substrate 2. More specifically, the plurality of second electrodes 5 are arranged directly on the substrate 2.

Furthermore, in the semiconductor device 1, each of the plurality of gate electrodes 6 is formed on the surface 321, intersecting with the first direction D1, of the second nitride semiconductor portion 32. In the semiconductor device 1, the plurality of semiconductor portions 3 correspond one to one to the plurality of gate electrodes 6. In addition, the plurality of gate electrodes 6 correspond one to one to the plurality of first electrodes 4. Furthermore, the plurality of gate electrodes 6 also correspond one to one to the plurality of second electrodes 5. Each of the plurality of gate electrodes 6 extends linearly in the second direction D2. That is to say, each of the plurality of gate electrodes 6 is arranged in the second direction D2. The plurality of gate electrodes 6 are arranged in the first direction D1 to be spaced apart from each other. Each of the plurality of gate electrodes 6 is separated in the third direction D3 from an associated one of the first electrodes 4 and an associated one of the second electrodes 5. The width as measured in the third direction D3 of each gate electrode 6 is shorter than the distance as measured in the third direction D3 between the first and second electrodes 4 and 5. The semiconductor device 1 further includes a third common electrode 60, to which a plurality of gate electrodes 6 are connected in common. In the semiconductor device 1, the first common electrode 40, the second common electrode 50, and the third common electrode 60 respectively constitute a common source electrode, a common drain electrode, and a common gate electrode.

Each of the plurality of first insulating layers 91 is arranged between an associated one of the second electrodes 5 and an associated one of the gate electrodes 6 in the gap between associated two of the plurality of semiconductor portions 3. The plurality of first insulating layers 91 may be made of silicon nitride, for example. However, this is only an example of the present disclosure and should not be construed as limiting. Alternatively, the plurality of first insulating layers 91 may also be made of silicon dioxide, for example.

Each of the plurality of second insulating layers 92 is arranged on an associated one of the first insulating layers 91 to cover an associated one of the gate electrodes 6 in the gap between associated two adjacent ones of the plurality of semiconductor portions 3. The plurality of second insulating layers 92 may be made of silicon nitride, for example. However, this is only an example of the present disclosure and should not be construed as limiting. Alternatively, the plurality of second insulating layers 92 may also be made of silicon dioxide, for example.

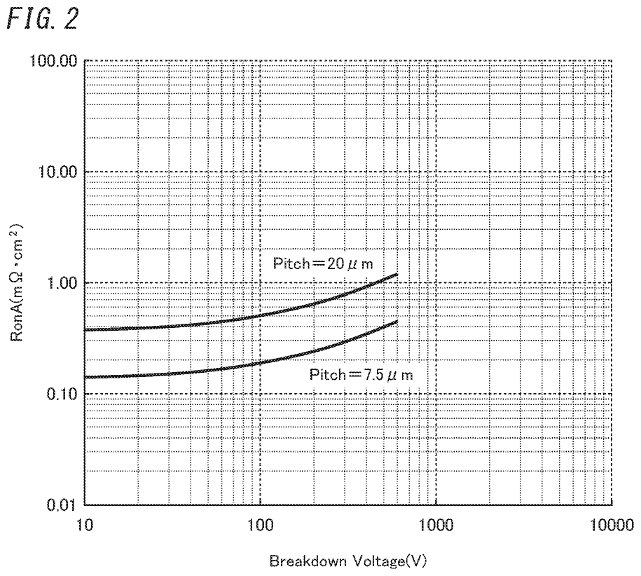

The semiconductor device 1 is able to increase the degree of integration of the plurality of semiconductor portions 3 and reduce the ON-state resistance of the semiconductor device 1 by shortening the pitch of the plurality of semiconductor portions 3 in the first direction D1 without changing the chip size of the semiconductor device 1. FIG. 2 shows the results of simulation of ON-state resistance-breakdown voltage characteristics corresponding to two different pitches in the first direction D1 between the plurality of semiconductor portions 3 of the semiconductor device 1. According to these simulations, the thickness as measured in the third direction D3 of the semiconductor portions 3 was supposed to be constant at 7.5 μm. As can be seen from FIG. 2, the ON-state resistance decreased when the pitch was 7.5 μm, compared to when the pitch was 20 μm.

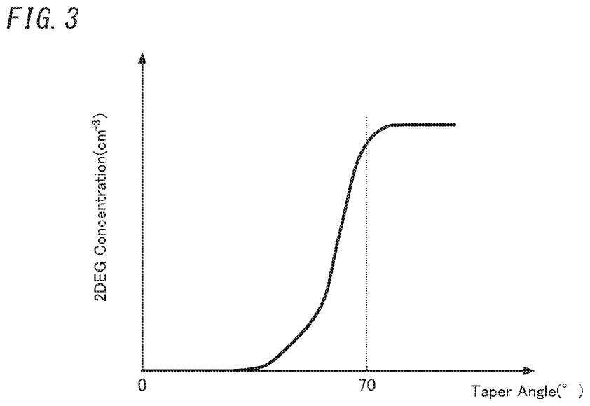

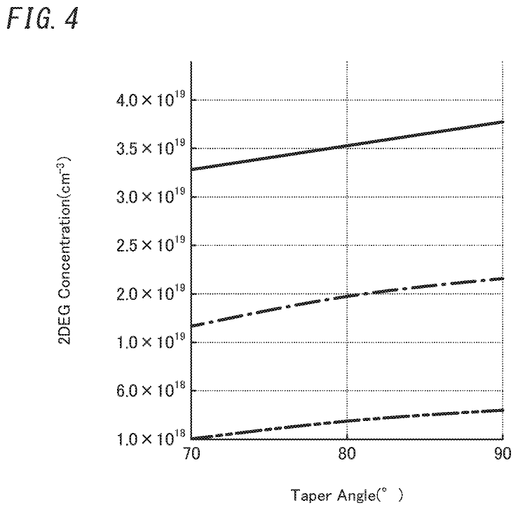

Furthermore, with an eye to increasing the degree of integration of the plurality of semiconductor portions 3 in the semiconductor device 1, the surface 321 intersecting with the first direction D1 of the second nitride semiconductor portion 32 suitably has a taper angle θ falling within the range from 70 degrees to 100 degrees, more suitably has a taper angle θ falling within the range from 80 degrees to 95 degrees, and even more suitably has a taper angle θ of approximately 90 degrees. From the viewpoint of curbing a decrease in the concentration of the two-dimensional electron gas 37 produced in each of the plurality of semiconductor portions 3, the semiconductor device 1 suitably has a taper angle θ equal to or greater than 70 degrees. FIGS. 3 and 4 show the results of simulations of relationship between the taper angle θ and the concentration of the two-dimensional electron gas of the semiconductor portions 3. Specifically, FIG. 3 shows the results of simulations obtained when the undoped AlGaN crystals forming the second nitride semiconductor portion 32 had an Al composition ratio (i.e., the mole fraction x in AlₓGa₁₋ₓN) of 0.25. Also, in FIG. 4, the solid curve represents the result of simulations obtained when the undoped AlGaN crystals forming the second nitride semiconductor portion 32 had an Al composition ratio of 0.25. That is to say, this portion of FIG. 4 is a partially enlarged one of FIG. 3. Meanwhile, in FIG. 4, the one-dot-chain curve represents the result of simulations obtained when the undoped AlGaN crystals forming the second nitride semiconductor portion 32 had an Al composition ratio of 0.20. Furthermore, in FIG. 4, the two-dot-chain curve represents the result of simulations obtained when the undoped AlGaN crystals forming the second nitride semiconductor portion 32 had an Al composition ratio of 0.15. As can be seen from FIGS. 3 and 4, setting the taper angle at 70 degrees or more curbs a decrease in the concentration of the two-dimensional electron gas.

Next, an exemplary method for fabricating the semiconductor device 1 will be described briefly with reference to FIGS. 5A-5C, FIGS. 6A-6C, FIGS. 7A-7D, and FIGS. 8A-8D.

According to a method for fabricating the semiconductor device 1, a mask portion forming step, a first epitaxial growth process, and a second epitaxial growth step are performed in this order to form a plurality of semiconductor portions 3. According to this method for fabricating the semiconductor device 1, after the second epitaxial growth step has been performed, a poly-crystal removing step, a mask portion removing step, a second electrode forming step, a first insulating layer forming step, a gate electrode forming step, a second insulating layer forming step, and a first electrode forming step are performed in this order.

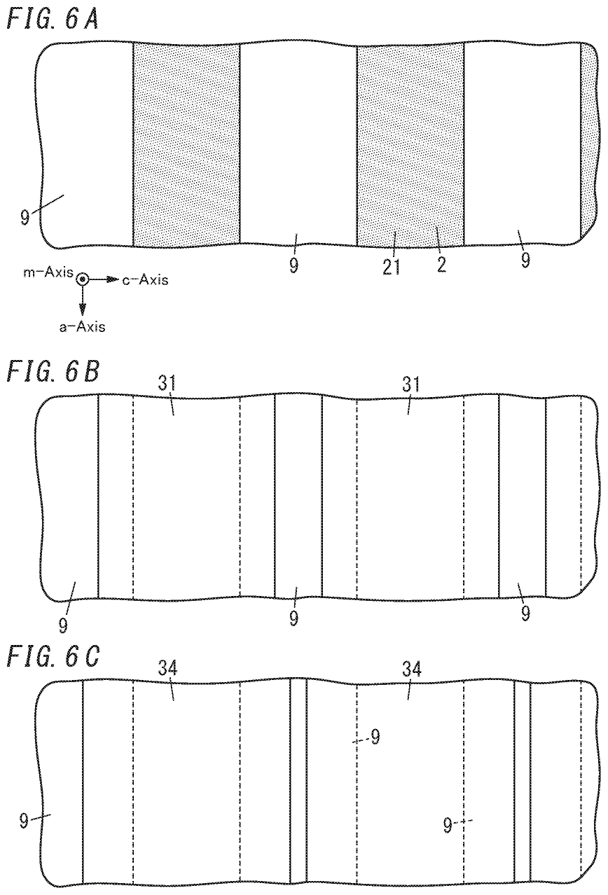

The mask portion forming step includes forming, on the first surface 21 of the substrate 2, a plurality of mask portions 9 extending linearly and arranged in a direction aligned with a c-axis of the substrate 2 (see FIGS. 5A and 6A). A material for the mask portions 9 may be silicon dioxide, for example. The mask portion forming step includes forming a plurality of mask portions 9 simultaneously by a thin film forming technique, a photolithographic technique, and an etching technique in combination.

The first epitaxial growth step includes forming a plurality of first nitride semiconductor portions 31 by epitaxial lateral overgrowth (ELO). Each of the plurality of first nitride semiconductor portions 31 covers a region between two adjacent ones of the plurality of mask portions 9 on the first surface 21 of the substrate 2 and respective surface portions of the two adjacent mask portions 9 (see FIGS. 5B and 6B). The ELO is a crystal-growing technique that adopts selective growth and lateral growth in combination. Specifically, a portion, designed to be formed directly on the first surface 21 of the substrate 2, of the first nitride semiconductor portion 31 is formed by selective growth, while a portion thereof designed to be formed on the mask portions 9 is formed by lateral growth. In the first epitaxial growth step, a metalorganic vapor phase epitaxy (MOVPE) system is used as an epitaxial growth system. In the first epitaxial growth step, trimethylgallium (TMGa), for example, may be used as a Ga source gas and NH₃, for example, may be used as an N source gas. A carrier gas for the respective source gases may be an H₂ gas, an N₂ gas, or a mixture of an H₂ gas and an N₂ gas, for example. As for conditions for growing the first nitride semiconductor portion 31, substrate temperature, V/III ratio, flow rates of the respective source gases, growth pressures, and other parameters may be set appropriately. As used herein, the “V/III ratio” refers to the ratio of the molar flow rate [μmol/min] of a source gas of a Group V element to the molar flow rate [μmol/min] of a source gas of a Group III element. The “growth pressure” refers herein to the pressure in the reaction furnace in a state where the respective source gases and carrier gases are being supplied into the reaction furnace of the MOVPE system.

The second epitaxial growth step includes epitaxially growing a plurality of second nitride semiconductor portions 32 on an associated one of the plurality of first nitride semiconductor portions 31 (see FIGS. 5C and 6C). In the second epitaxial growth step, a metalorganic vapor phase epitaxy (MOVPE) system is used as an epitaxial growth system. The second epitaxial growth step is performed continuously with the first epitaxial growth step in the MOVPE system in which the first epitaxial growth step has been performed. In the second epitaxial growth step, trimethylaluminum (TMAl), for example, may be used as an Al source gas, trimethylgallium (TMGa), for example, may be used as a Ga source gas, and NH₃, for example, may be used as an N source gas. A carrier gas for the respective source gases may be an H₂ gas, an N₂ gas, or a mixture of an H₂ gas and an N₂gas, for example. As for conditions for growing the second nitride semiconductor portion 32, substrate temperature, V/III ratio, flow rates of the respective source gases, growth pressures, and other parameters may be set appropriately. As used herein, the “V/III ratio” refers to the ratio of the molar flow rate [μmol/min] of a source gas of a Group V element to the molar flow rate [μmol/min] of a source gas of a Group III element.

According to the method for fabricating the semiconductor device 1, in the second epitaxial growth step, while a plurality of second nitride semiconductor portions 32, corresponding one to one to a plurality of first nitride semiconductor portions 31, are epitaxially grown on the plurality of first nitride semiconductor portions 31, a plurality of third nitride semiconductor portions 33 and a plurality of fourth nitride semiconductor portions 34 are epitaxially grown on the plurality of first nitride semiconductor portions 31 and polycrystalline AlGaN 39 is deposited on a plurality of mask portions 9. While the plurality of second nitride semiconductor portions 32 are epitaxially grown on the plurality of first nitride semiconductor portions 31, the polycrystalline AlGaN 39 is deposited on each mask portion 9. Part of each of the plurality of fourth nitride semiconductor portions 34 to be grown in the second epitaxial growth step forms the basis of an alloy portion 42 of its associated first electrode 4.

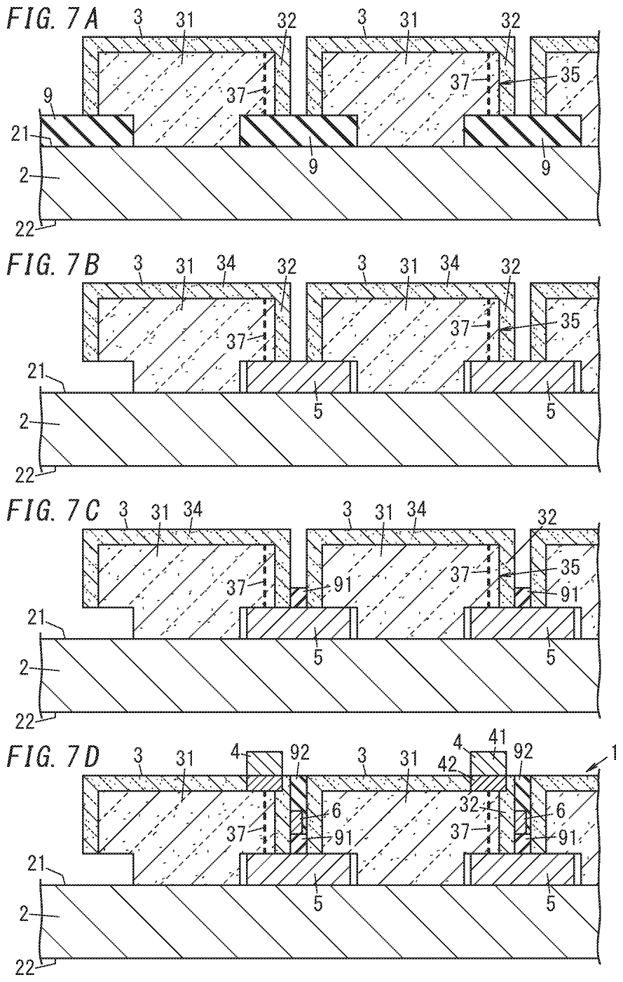

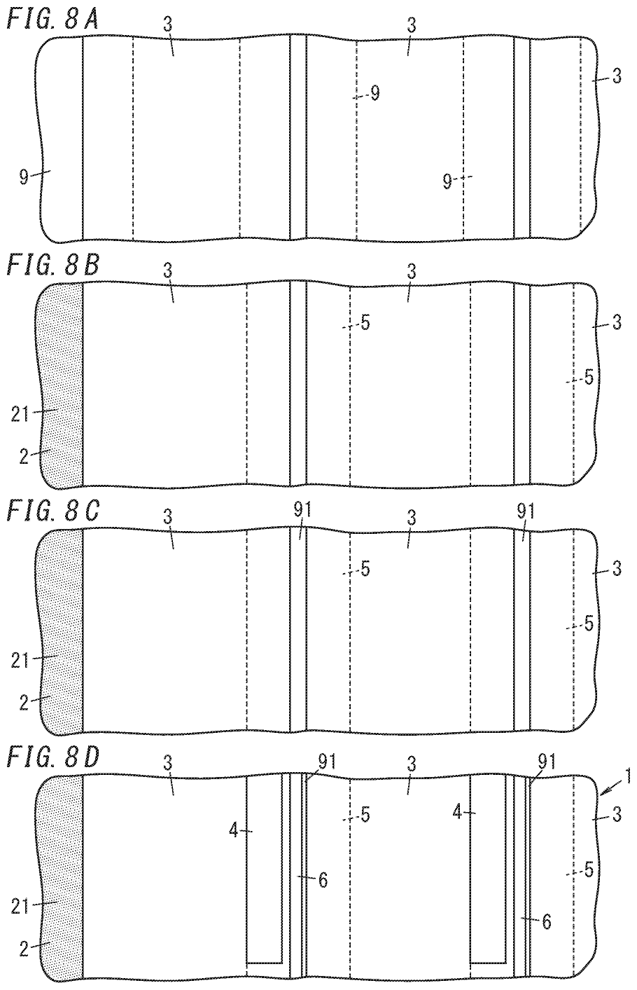

The poly-crystal removing step includes etching and thereby removing the polycrystalline AlGaN 39 formed on each of the plurality of mask portions 9 (see FIGS. 7A and 8A). In the poly-crystal removing step, the polycrystalline AlGaN may be selectively etched with a tetra-methyl-ammonium hydroxide (TMAH) solution, for example. Setting the temperature of the TMAH solution at around 80° C. allows the etch time to be shortened compared to setting the temperature of the TMAH solution at room temperature.

The mask portion removing step includes etching and thereby removing the plurality of mask portions 9.

The second electrode forming step includes forming a plurality of second electrodes 5 on respective regions, which have been covered with the plurality of mask portions 9, on the first surface 21 of the substrate 2. The second electrode forming step includes forming the plurality of second electrodes 5 by supplying and curing a liquid electrically conductive material onto the respective regions (see FIGS. 7B and 8B). The second electrode forming step may include forming a second common electrode 50 along with the plurality of second electrodes 5.

The first insulating layer forming step includes forming a plurality of first insulating layers 91 on the plurality of second electrodes 5 (see FIGS. 7C and 8C). More specifically, the first insulating layer forming step includes depositing a first insulating film to be the plurality of first insulating layers 91 by chemical vapor deposition (CVD) or any other process such that the first insulating film covers the plurality of second electrodes 5 and then etching back the first insulating film to form a plurality of first insulating layers 91, each being a part of the first insulating film.

The gate electrode forming step includes forming a plurality of gate electrodes 6 by evaporation and heat treatment (such as sintering) techniques (see FIGS. 7D and 8D). The gate electrode forming step may include forming a third common electrode 60 along with the plurality of gate electrodes 6.

The second insulating layer forming step includes depositing a second insulating film to be a plurality of second insulating layers 92 by CVD or any other process such that the second insulating film covers the plurality of first insulating layers 91 and the plurality of gate electrodes 6 and then etching back the second insulating film to form a plurality of second insulating layers 92 (see FIG. 7D).

The first electrode forming step includes forming a metallic portion 41 on each of the plurality of semiconductor portions 3 and then forming an alloy portion 42 through sintering to form a plurality of first electrodes 4, each including the metallic portion 41 and the alloy portion 42 (see FIGS. 7D and 8D). The first electrode forming step includes forming the alloy portion 42 by causing, through sintering, the metal in the metallic portion 41 to diffuse toward a portion, located right under the metallic portion 41, of each of the fourth nitride semiconductor portions 34. The first electrode forming step may include forming a first common electrode 40 along with the plurality of first electrodes 4.

According to the method for fabricating the semiconductor device 1, a wafer, from which a plurality of semiconductor devices 1 are formed, may be obtained by using a wafer that forms the basis of the substrates 2 until the first electrode forming step is finished. According to the method for fabricating the semiconductor device 1, a plurality of semiconductor devices 1 may be obtained by cutting off, with a dicing saw, for example, the wafer on which a plurality of semiconductor devices 1 have been formed.

The semiconductor device 1 according to the first embodiment described above contributes to reducing the electrical resistance between the first common electrode 40 and the second common electrode 50. More specifically, the semiconductor device 1 according to the first embodiment contributes to reducing the ON-state resistance. In this case, the semiconductor device 1 contributes to reducing the ON-state resistance while increasing the breakdown voltage. The longer the distance between the first electrode 4 and the second electrode 5 in the third direction is, the more significantly the semiconductor device 1 may increase the breakdown voltage. The distance between the first electrode 4 and the second electrode 5 may be increased by thickening the first nitride semiconductor portion 31 in the third direction D3.

The larger the number of the first heterojunctions 35 is, the more significantly the semiconductor device 1 may reduce the electrical resistance. Thus, RonA (which is ON-state resistance per unit area and of which the unit is Ω·cm²) of the semiconductor device 1 may be reduced by increasing the number of the first heterojunctions 35 with the interval between the first heterojunctions 35 adjacent to each other in the second direction D2 shortened. As used herein, RonA is the product of Ron (i.e., the ON-state resistance (Ω)) and the area of the semiconductor device 1 (which is the chip area of the semiconductor device 1 in a plan view and which may be 1 cm×1 cm=1 cm², for example).

In addition, as the length of the first heterojunction 35 as measured perpendicularly to the first direction D1 and the second direction D2 is increased, the semiconductor device 1 may reduce RonA even more significantly.

### Advantages

The semiconductor device 1 according to the first embodiment includes a plurality of semiconductor portions 3, a plurality of first electrodes 4, a plurality of second electrodes 5, a first common electrode 40, and a second common electrode 50. The plurality of semiconductor portions 3 are arranged in a first direction D1 to be spaced apart from each other. Each of the plurality of semiconductor portions 3 has a heterojunction 35 between a first nitride semiconductor portion 31 and a second nitride semiconductor portion 32 having a larger bandgap than the first nitride semiconductor portion 31. The heterojunction 35 of each of the plurality of semiconductor portions 3 extends in a second direction D2 perpendicular to a first direction D1 aligned with a c-axis of the first nitride semiconductor portion 31. Each of the plurality of first electrodes 4 overlaps with an associated one of the plurality of semiconductor portions 3 in a third direction D3 perpendicular to both of the first direction D1 and the second direction D2. Each of the plurality of first electrodes 4 is directly electrically connected to the heterojunction 35 of the associated semiconductor portion 3. Each of the plurality of second electrodes 5 is located, with respect to an associated one of the plurality of semiconductor portions 3, opposite in the third direction D3 from one of the plurality of first electrodes 4 that overlaps with the associated semiconductor portion 3 such that the associated semiconductor portion 3 is sandwiched between the first electrode 4 and the second electrode 5. Each of the plurality of second electrodes 5 is directly electrically connected to the heterojunction 35 of the associated semiconductor portion 3. The plurality of first electrodes 4 are electrically connected in common to the first common electrode 40. The plurality of second electrodes 5 are electrically connected in common to the second common electrode 50.

The semiconductor device 1 according to the first embodiment contributes to reducing the electrical resistance.

### Variations of First Embodiment

Note that the first embodiment described above is only an exemplary one of various embodiments of the present disclosure and should not be construed as limiting. Rather, the first exemplary embodiment may be readily modified in various manners depending on a design choice or any other factor without departing from the scope of the present disclosure.

For example, a semiconductor device 1 according to a first variation of the first embodiment may further include a plurality of gate layers. Each of the plurality of gate layers is interposed, in the first direction D1, between an associated one of the gate electrodes 6 and an associated one of the semiconductor portions 3. More specifically, each of the plurality of gate layers is interposed, in the first direction D1, between the associated gate electrode 6 and an associated one of the second nitride semiconductor portions 32. Each of the plurality of gate layers forms a depletion layer between the associated second nitride semiconductor portion 32 and an associated one of the first nitride semiconductor portions 31. Each of the plurality of gate layers forms a depletion layer in the associated semiconductor portion 3 when no voltage is applied between an associated one of the gate electrodes 6 and an associated one of the source electrodes 4 or between an associated one of the drain electrodes 5 and the associated source electrode 4. Thus, this first variation provides a normally OFF field-effect transistor. According to the first variation, when voltage to turn the semiconductor device 1 ON is applied between the associated gate electrode 6 and the associated source electrode 4 and voltage is applied between the associated drain electrode 5 and the associated source electrode 4, the associated source electrode 4 and drain electrode 5 may be connected together with the two-dimensional electron gas 37. In other words, this first variation prevents the two-dimensional electron gas 37 from being interrupted by the depletion layer halfway between the source electrode 4 and drain electrode 5 that face each other in the third direction D3.

Each of the plurality of gate layers may be a p-type semiconductor layer, for example. In this embodiment, the p-type semiconductor layer may be a metal oxide layer, for example. A metal oxide layer serving as the p-type semiconductor layer may be an NiO layer, for example. Optionally, the NiO layer may contain, as an impurity, at least one alkali metal selected from the group consisting of lithium (Li), sodium (Na), potassium (K), rubidium (Rb), and cesium (Cs). The NiO layer may also contain, for example, a transition metal such as silver (Ag) or copper (Cu) which becomes univalent when added as an impurity. When measured in the first direction D1, the thickness of each gate layer may be 100 nm, for example. Note that each gate layer has only to be a p-type semiconductor layer and does not have to be an NiO layer but may also be a p-type AlGaN layer or a p-type GaN layer, for example.

Meanwhile, a semiconductor device 1 according to a second variation of the first embodiment does not include the gate electrode 6 of the semiconductor device 1 according to the first embodiment. According to the second variation, as in the semiconductor device 1 according to the first embodiment, a plurality of double heterostructures 30 are arranged side by side in the first direction D1, and therefore, undoped AlGaN crystals and undoped GaN crystals are arranged alternately in the first direction D1. Thus, according to the second variation, a plurality of two-dimensional electron gases 37 and a plurality of two-dimensional hole gases are arranged alternately in the first direction D1. Furthermore, according to the second variation, the width as measured in the first direction D1 of each first electrode 4 is approximately equal to the width as measured in the first direction D1 of its associated semiconductor portion 3, and the first electrode 4 is directly electrically connected to the first heterojunction 35 and the second heterojunction 36. Furthermore, according to the second variation, each second electrode 5 is directly electrically connected to the first heterojunction 35 of one of two semiconductor portions 3 that are adjacent to each other in the first direction D1 and is also directly electrically connected to the second heterojunction 36 of the other semiconductor portion 3. In this case, according to the second variation, a Schottky barrier diode is formed. Furthermore, according to the second variation, with respect to the two-dimensional electron gas 37, either the first electrode 4 or the second electrode 5 is formed of a metal with a relatively large work function (i.e., a metal to form a p-electrode) without sintering and electrically connected. With respect to a two-dimensional hole gas, on the other hand, either the first electrode 4 or the second electrode 5 is formed of a metal with a relatively small work function (i.e., a metal to form an n-electrode) with sintering. Furthermore, according to the second variation, one of the first electrode 4 or the second electrode 5 constitutes an anode electrode, while the other constitutes a cathode electrode. According to the second variation, either the first electrode 4 or the second electrode 5 having the higher potential when voltage is applied between the first electrode 4 and the second electrode 5 constitutes the anode electrode and either the first electrode 4 or the second electrode 5 having the lower potential when voltage is applied between the first electrode 4 and the second electrode 5 constitutes the cathode electrode. The second variation is implemented as a multi-channel diode.

Furthermore, according to the second variation, in each of the plurality of double heterostructures 30, the third nitride semiconductor portion 33, the first nitride semiconductor portion 31, and the second nitride semiconductor portion 32 are arranged in this order in the first direction D1. Each of the plurality of double heterostructures 30 includes a first heterojunction 35 as a heterojunction between the first nitride semiconductor portion 31 and the second nitride semiconductor portion 32 and a second heterojunction 36 as a heterojunction between the first nitride semiconductor portion 31 and the third nitride semiconductor portion 33. According to the second variation, one of the first electrode 4 or the second electrode 5 constitutes an anode electrode and the other constitutes a cathode electrode. Thus, this second variation provides a diode contributing to reducing the electrical resistance while increasing the breakdown voltage.

Furthermore, in the semiconductor device 1 described above, the first electrode 4 and the second electrode 5 serve as a source electrode and a drain electrode, respectively. However, this is only an example of the present disclosure and should not be construed as limiting. Alternatively, the first electrode 4 and the second electrode 5 may serve as a drain electrode and a source electrode, respectively.

Furthermore, the nitride semiconductor substrate serving as the substrate 2 does not have to be a GaN substrate but may also be an AlN substrate, for example.

Furthermore, in the embodiment described above, the plurality of semiconductor portions 3 are arranged at regular intervals in the first direction D1. However, the plurality of semiconductor portions 3 do not have to be arranged at regular intervals.

Optionally, the semiconductor device 1 may include a plurality of passivation portions, each of which is provided between two adjacent ones of the plurality of semiconductor portions 3 to cover the gate electrode 6 arranged between the two semiconductor portions 3. Each of the plurality of passivation portions has electrical insulation properties. Each of the plurality of passivation portions may be made of silicon dioxide, for example. However, this is only an example of the present disclosure and should not be construed as limiting. Alternatively, each of the plurality of passivation portions may also be made of silicon nitride, for example.

In addition, the semiconductor device 1 does not have to include a plurality of second electrodes 5. For example, in the method for fabricating the semiconductor device 1 described above, a sapphire substrate may be adopted as the substrate 2, a plurality of semiconductor portions 3 may be formed thereon and transferred, and then the substrate 2 may be removed. After that, a plurality of second electrodes 5 may be formed thereon. Alternatively, a single second electrode 5 covering a plurality of semiconductor portions 3 may also be formed.

Furthermore, the epitaxial growth process to form the first nitride semiconductor portion 31 does not have to be MOVPE but may also be hydride vapor phase epitaxy (HVPE). Likewise, the epitaxial growth process to form the second nitride semiconductor portions 32, the third nitride semiconductor portions 33, and the fourth nitride semiconductor portions 34 does not have to be MOVPE but may also be HYPE. The undoped GaN crystals and the undoped AlGaN crystals may include Mg, H, Si, C, O, and other impurities to be inevitably contained during their growth.

### Second Embodiment

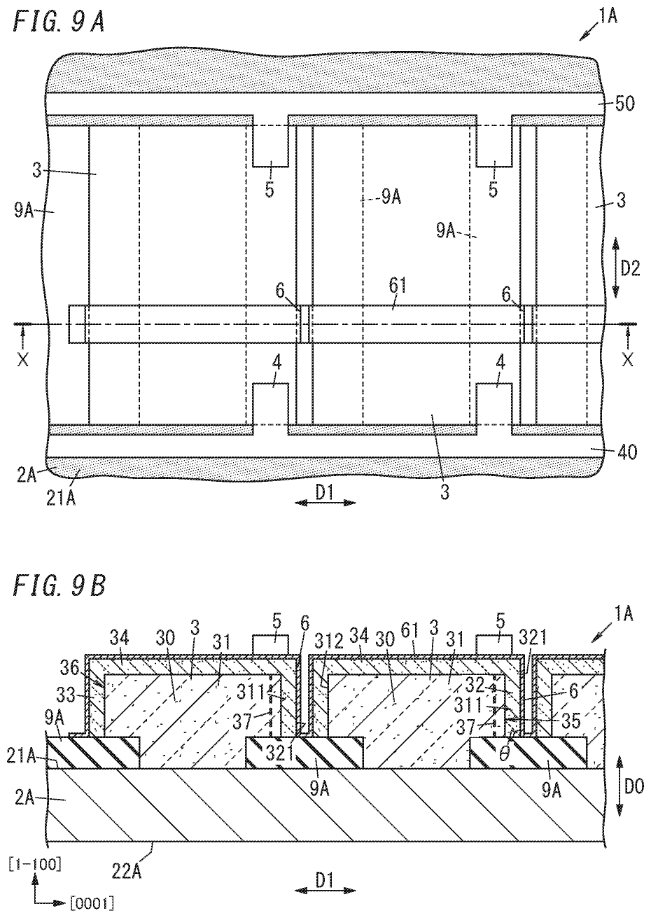

Next, a semiconductor device 1A according to a second embodiment will be described with reference to FIGS. 9A and 9B.

The semiconductor device 1A includes a nitride semiconductor substrate 2A, a plurality of insulator portions 9A, a plurality of semiconductor portions 3, a plurality of first electrodes 4, a plurality of second electrodes 5, a first common electrode 40, and a second common electrode 50. The nitride semiconductor substrate 2A has a first surface 21A and a second surface 22A located opposite from each other in a thickness direction D0. The first surface 21A of the nitride semiconductor substrate 2A is a crystallographic plane aligned with a c-axis. Each of the plurality of insulator portions 9A is elongated linearly in a second direction D2 perpendicular to both the thickness direction D0 defined for the nitride semiconductor substrate 2A and a first direction D1 aligned with the c-axis of the nitride semiconductor substrate 2A. The plurality of insulator portions 9A are arranged side by side in the first direction D1 on the first surface 21A of the nitride semiconductor substrate 2A. The plurality of semiconductor portions 3 are arranged in the first direction D1 to be spaced apart from each other. Each of the plurality of semiconductor portions 3 includes a first nitride semiconductor portion 31 and a second nitride semiconductor portion 32. The first nitride semiconductor portion 31 is formed on a region between two adjacent ones of the plurality of insulator portions 9A on the first surface 21A of the nitride semiconductor substrate 2A and extends over the two adjacent insulator portions 9A. The second nitride semiconductor portion 32 is directly formed on one surface 311, aligned with a +c plane, out of two surfaces 311, 312 intersecting with the first direction D1 in the first nitride semiconductor portion 31. Each of the plurality of first electrodes 4 is electrically connected to a heterojunction 35 between the first nitride semiconductor portion 31 and the second nitride semiconductor portion 32 of an associated one of the plurality of semiconductor portions 3. Each of the plurality of second electrodes 5 is also electrically connected to the heterojunction 35 between the first nitride semiconductor portion 31 and the second nitride semiconductor portion 32 of an associated one of the plurality of semiconductor portions 3. Each of the plurality of second electrodes 5 is spaced in the second direction D2 from an associated one of the plurality of first electrodes 4. The plurality of first electrodes 4 are electrically connected in common to the first common electrode 40. The plurality of second electrodes 5 are electrically connected in common to the second common electrode 50. In FIG. 9A, the nitride semiconductor substrate 2A is hatched with dots. Note that this hatching does not indicate a cross section but is just provided there to clarify the relationship between the nitride semiconductor substrate 2A and the other constituent elements (including the respective semiconductor portions 3, the respective first electrodes 4, the respective second electrodes 5, the first common electrode 40, and the second common electrode 50).

A semiconductor device 1A according to the second embodiment is implemented as a field-effect transistor chip, and further includes a plurality of third electrodes 6 provided separately from the plurality of first electrodes 4 and the plurality of second electrodes 5. In the semiconductor device 1A according to this embodiment, the plurality of first electrodes 4, the plurality of second electrodes 5, and the plurality of third electrodes 6 respectively constitute a plurality of source electrodes, a plurality of drain electrodes, and a plurality of gate electrodes. In the following description, the plurality of first electrodes 4, the plurality of second electrodes 5, and the plurality of second electrodes 6 will be hereinafter sometimes referred to as “a plurality of source electrodes 4,” “a plurality of drain electrodes 5,” and “a plurality of gate electrodes 6,” respectively, for the sake of convenience.

The respective constituent elements of the semiconductor device 1A will be described in further detail.

When viewed in plan in the thickness direction defined with respect to the semiconductor device 1A, the semiconductor device 1A may have a square outer peripheral shape, for example. When viewed in plan in the thickness direction defined with respect to the semiconductor device 1A, the semiconductor device 1A may have a chip size of 5 mm square (5 mm×5 mm), for example. Note that this numerical value is only an example and should not be construed as limiting. In addition, the semiconductor device 1A does not have to have a square outer peripheral shape, either, but may have a rectangular outer peripheral shape as well.

The nitride semiconductor substrate 2A supports the semiconductor portions 3 thereon. The nitride semiconductor substrate 2A may be a single-crystal GaN substrate, for example. Therefore, the nitride semiconductor substrate 2A has a hexagonal crystal structure. The first direction D1 is defined along a c-axis of the nitride semiconductor substrate 2A (which may be parallel to the c-axis of the nitride semiconductor substrate 2A, for example). The c-axis of the nitride semiconductor substrate 2A points to the right in each of FIGS. 9A and 9B. At the lower left corner of FIG. 9B, shown are a crystallographic axis [0001] indicating the c-axis of the nitride semiconductor substrate 2A and a crystallographic axis [1-100] indicating the m-axis thereof. The single crystal GaN substrate may be a semi-insulating GaN substrate, for example.

The nitride semiconductor substrate 2A has a first surface 21A located in the thickness direction D0 closer to the plurality of semiconductor portions 3 and a second surface 22A located in the thickness direction D0 more distant from the plurality of semiconductor portions 3. In this case, the first surface 21A of the nitride semiconductor substrate 2A is an m-plane, which may be a (1-100) plane, for example. As used herein, the negative sign “−” added to a Miller index representing a crystallographic plane orientation indicates the inversion of the index following the negative sign. The (1-100) plane is a crystallographic plane represented by four Miller indices enclosed in parentheses.

The first surface 21A of the nitride semiconductor substrate 2A may be a nonpolar plane aligned with the c-axis and does not have to be an m-plane but may be an a-plane as well. The a-plane may be a (11-20) plane, for example. Alternatively, the first surface 21A of the nitride semiconductor substrate 2A may also be a crystallographic plane, of which an off-axis angle with respect to an m-plane (hereinafter referred to as a “first off-axis angle”) is greater than 0 degrees and equal to or less than 5 degrees. As used herein, the “first off-axis angle” indicates a tilt angle of the first surface 21A with respect to the m-plane. Thus, if the first off-axis angle is 0 degrees, then the first surface 21A is an m-plane. Likewise, the first surface 21A of the nitride semiconductor substrate 2A may also be a crystallographic plane, of which an off-axis angle with respect to an a-plane (hereinafter referred to as a “second off-axis angle”) is greater than 0 degrees and equal to or less than 5 degrees. As used herein, the “second off-axis angle” indicates a tilt angle of the first surface 21A with respect to the a-plane. Thus, if the second off-axis angle is 0 degrees, then the first surface 21A is an a-plane. The nitride semiconductor substrate 2A may have a thickness falling within the range from 100 μm to 700 μm, for example.

Each of the plurality of insulator portions 9A is linearly elongated in the second direction D2. The plurality of insulator portions 9A are arranged side by side in the first direction D1 on the first surface 21A of the nitride semiconductor substrate 2A. Each of the plurality of insulator portions 9A may be made of silicon dioxide. However, this is only an example of the present disclosure and should not be construed as limiting. Alternatively, each of the plurality of insulator portions 9A may also be made of silicon nitride. Still alternatively, each of the plurality of insulator portions 9A may also be a stack of a silicon dioxide film and a silicon nitride film.

The plurality of semiconductor portions 3 are arranged side by side in the first direction D1 to be spaced apart from each other. Each of the plurality of semiconductor portions 3 includes a first nitride semiconductor portion 31 and a second nitride semiconductor portion 32, of which the magnitudes of bandgaps are different from each other. The composition of the second nitride semiconductor portion 32 is different from that of the first nitride semiconductor portion 31. In each of the plurality of semiconductor portions 3, the first nitride semiconductor portion 31 and the second nitride semiconductor portion 32 are arranged side by side in the first direction D1. Also, each of the plurality of semiconductor portions 3 further includes a third nitride semiconductor portion 33, of which the magnitude of bandgap is different from that of the first nitride semiconductor portion 31. The composition of the third nitride semiconductor portion 33 may be the same as that of the second nitride semiconductor portion 32, for example.

The third nitride semiconductor portion 33 is located opposite in the first direction D1 from the second nitride semiconductor portion 32 with respect to the first nitride semiconductor portion 31.

Each of the plurality of semiconductor portions 3 further includes a fourth nitride semiconductor portion 34, of which the magnitude of bandgap is different from that of the first nitride semiconductor portion 31. The composition of the fourth nitride semiconductor portion 34 may be the same as that of the second nitride semiconductor portion 32, for example. The fourth nitride semiconductor portion 34 is located between an end portion, opposite from the nitride semiconductor substrate 2A, of the second nitride semiconductor portion 32 and an end portion, opposite from the nitride semiconductor substrate 2A, of the third nitride semiconductor portion 33 in the associated semiconductor portion 3.

In each of the plurality of semiconductor portions 3, when measured in the first direction D1, the respective thicknesses of the second nitride semiconductor portion 32 and the third nitride semiconductor portion 33 are smaller than the thickness of the first nitride semiconductor portion 31. In addition, in each of the plurality of semiconductor portions 3, when measured in the thickness direction D0 defined for the nitride semiconductor substrate 2A, the thickness of the fourth nitride semiconductor portion 34 is smaller than the thickness of the first nitride semiconductor portion 31.

As measured in the thickness direction D0 defined for the nitride semiconductor substrate 2A, the thickness of the first nitride semiconductor portion 31 may be 7.5 μm, for example. However, this is only an example of the present disclosure and should not be construed as limiting. Rather the thickness of the first nitride semiconductor portion 31 suitably falls within the range from 5 μm to 30 μm, for example. Also, the thickness of the first nitride semiconductor portion 31 as measured in the first direction D1 may be 4 μm, for example. Furthermore, the respective thicknesses of the second nitride semiconductor portion 32 and the third nitride semiconductor portion 33 as measured in the first direction D1 may be 20 nm, for example. The thickness of the fourth nitride semiconductor portion 34 as measured in the thickness direction D0 defined for the nitride semiconductor substrate 2A may be 20 nm, for example.

The first nitride semiconductor portion 31 may be made up of undoped GaN crystals, for example. Each of the second nitride semiconductor portion 32, the third nitride semiconductor portion 33, and the fourth nitride semiconductor portion 34 may be made up of undoped AlGaN crystals. Each of the first nitride semiconductor portion 31, the second nitride semiconductor portion 32, the third nitride semiconductor portion 33, and the fourth nitride semiconductor portion 34 may be an epitaxial layer. In each of the plurality of semiconductor portions 3, the second nitride semiconductor portion 32, the third nitride semiconductor portion 33, and the fourth nitride semiconductor portion 34 may have the same Al composition ratio (of 0.25, for example). However, this is only an example and should not be construed as limiting. Alternatively, the second, third, and fourth nitride semiconductor portions 32, 33, and 34 may have different Al composition ratios. In this specification, the composition ratio may be a value obtained by composition analysis according to energy dispersive X-ray spectroscopy (EDX). When their magnitudes are discussed, the composition ratios do not have to be values obtained by the EDX but may also be values obtained by composition analysis according to Auger electron spectroscopy, for example.

Each of the plurality of semiconductor portions 3 has the heterojunction 35 defining a junction between the first nitride semiconductor portion 31 and the second nitride semiconductor portion 32 (hereinafter referred to as a “first heterojunction 35”). The first heterojunction 35 intersects (e.g., at right angles in this embodiment) with the first direction D1 aligned with the first surface 21A of the nitride semiconductor substrate 2A. Each of the plurality of semiconductor portions 3 also has a heterojunction 36 defining a junction between the first nitride semiconductor portion 31 and the third nitride semiconductor portion 33 (hereinafter referred to as a “second heterojunction 36”). The second heterojunction 36 intersects (e.g., at right angles in this embodiment) with the first direction D1 aligned with the first surface 21A of the nitride semiconductor substrate 2A. The first heterojunction 35 and the second heterojunction 36 may extend in the second direction D2. However, the first heterojunction 35 and the second heterojunction 36 do not always intersect at right angles with the first direction D1 (i.e., the angle formed between each of the first heterojunction 35 and the second heterojunction 36 and the first direction D1 is not always 90 degrees). In other words, the angle (interior angle) formed between the first heterojunction 35 and a surface, parallel to the first surface 21A of the nitride semiconductor substrate 2A, of the insulator portion 9A in the semiconductor portion 3 does not have to be 90 degrees but may fall within the range from 70 degrees to 100 degrees. The angle (interior angle) formed between the second heterojunction 36 and a surface, parallel to the first surface 21A of the nitride semiconductor substrate 2A, of the insulator portion 9A in the semiconductor portion 3 does not have to be 90 degrees but may fall within the range from 70 degrees to 100 degrees.

The first nitride semiconductor portion 31 is formed directly on the first surface 21A of the nitride semiconductor substrate 2A. In this embodiment, the first nitride semiconductor portion 31 is formed on a region between two adjacent ones of the plurality of insulator portions 9A on the first surface 21A of the nitride semiconductor substrate 2A and extends to cover the two insulator portions 9A.

The second nitride semiconductor portion 32 is formed directly on the surface 311, aligned with a +c plane, out of the two surfaces 311, 312 intersecting with the first direction D1 of the first nitride semiconductor portion 31. Note that the surface 312 is aligned with a −c plane.

The first nitride semiconductor portion 31 has a surface 311 (hereinafter referred to as a “first surface 311”) and a surface 312 (hereinafter referred to as a “second surface 312”), which are located opposite from each other in the first direction D1. In other words, the first nitride semiconductor portion 31 has a first surface 311 and a second surface 312, which intersect with the first direction D1 and which are spaced apart from each other in the first direction D1. The first surface 311 is a Group III polar plane (a Ga polar plane in this embodiment) of the first nitride semiconductor portion 31. The Ga polar plane (+c plane) is a (0001) plane. The first surface 311 does not have to be a Group III polar plane but may also be a crystallographic plane forming a tilt angle of 1 to 30 degrees with respect to the Group III polar plane. The second surface 312 is a Group V polar plane (an N polar plane in this embodiment) of the first nitride semiconductor portion 31. The N polar plane (−c plane) is a (000-1) plane. The second surface 312 does not have to be a Group V polar plane but may also be a crystallographic plane forming a tilt angle of 1 to 30 degrees with respect to the Group V polar plane.

In each of the plurality of semiconductor portions 3, the first heterojunction 35 is formed to include the first surface 311 of the first nitride semiconductor portion 31. In addition, in each of the plurality of semiconductor portions 3, the second heterojunction 36 is formed to include the second surface 312 of the first nitride semiconductor portion 31.

In each of the plurality of semiconductor portions 3, in the vicinity of the first heterojunction 35 intersecting with the first direction D1, a two-dimensional electron gas 37 has been generated by spontaneous polarization and piezoelectric polarization of a nitride semiconductor (e.g., undoped AlGaN crystals that form the second nitride semiconductor portion 32 in this embodiment). In other words, in each of the plurality of semiconductor portions 3, the first heterojunction 35 generates the two-dimensional electron gas 37. A region including the two-dimensional electron gas 37 (hereinafter referred to as a “two-dimensional electron gas layer”) may function as an n-channel layer (electron conduction layer). In addition, in each of the plurality of semiconductor portions 3, in the vicinity of the second heterojunction 36 intersecting with the first direction D1, a two-dimensional hole gas has been generated by spontaneous polarization and piezoelectric polarization of a nitride semiconductor (e.g., undoped AlGaN crystals that form the third nitride semiconductor portion 33 in this embodiment). In other words, in each of the plurality of semiconductor portions 3, the second heterojunction 36 generates the two-dimensional hole gas. A region including the two-dimensional hole gas (hereinafter referred to as a “two-dimensional hole gas layer”) may function as a p-channel layer (hole conduction layer).

The semiconductor device 1A suitably includes a plurality of (e.g., 1,000) double heterostructures 30, which are arranged side by side in the first direction D1 to be separated from each other. In each of the plurality of double heterostructures 30, the third nitride semiconductor portion 33, the first nitride semiconductor portion 31, and the second nitride semiconductor portion 32 are arranged in this order in the first direction D1.

Each of the double heterostructures 30 has the first heterojunction 35 and the second heterojunction 36 described above. Thus, the semiconductor device 1A includes a plurality of (e.g., 1,000) first heterojunctions 35 and a plurality of (e.g., 1,000) second heterojunctions 36. In this embodiment, in the semiconductor device 1A, the plurality of first heterojunctions 35 extend parallel to each other, and the plurality of second heterojunctions 36 also extend parallel to each other. In this semiconductor device 1A, the plurality of first heterojunctions 35 are arranged in the first direction D1 at generally regular intervals. Also, in this semiconductor device 1A, the interval between the respective surfaces 321 of the second nitride semiconductor portions 32 of the two semiconductor portions 3 adjacent to each other in the first direction D1 (i.e., a pitch between a plurality of semiconductor portions 3) may be 7.5 μm, for example.

The semiconductor device 1A suitably includes a plurality of (e.g., 1,000) double heterostructures 30, which are arranged side by side in the first direction D1 to be separated from each other. In each of the plurality of double heterostructures 30, the third nitride semiconductor portion 33, the first nitride semiconductor portion 31, and the second nitride semiconductor portion 32 are arranged in this order in the first direction D1.

Each of the double heterostructures 30 has the first heterojunction 35 and the second heterojunction 36 described above. Thus, the semiconductor device 1A includes a plurality of (e.g., 1,000) first heterojunctions 35 and a plurality of (e.g., 1,000) second heterojunctions 36. In this embodiment, in the semiconductor device 1A, the plurality of first heterojunctions 35 extend parallel to each other, and the plurality of second heterojunctions 36 also extend parallel to each other. In this semiconductor device 1A, the plurality of first heterojunctions 35 are arranged in the first direction D1 at generally regular intervals. Also, in this semiconductor device 1A, the interval between the respective surfaces 321 of the second nitride semiconductor portions 32 of the two semiconductor portions 3 adjacent to each other in the first direction D1 (i.e., a pitch between a plurality of semiconductor portions 3) may be 7.5 μm, for example.

In addition, in the semiconductor device 1A, the plurality of semiconductor portions 3 correspond one to one to the plurality of first electrodes 4. Each of the plurality of first electrodes 4 is an upper electrode provided on the semiconductor portion 3 at one end thereof in the second direction D2. The plurality of first electrodes 4 are arranged in the first direction D1 to be spaced apart from each other. In the semiconductor device 1A, each of the plurality of first electrodes 4 is directly electrically connected to the heterojunction 35 of its associated semiconductor portion 3. As used herein, to be “electrically connected to” means making ohmic contact with. Also, as used herein, to be “directly electrically connected to the heterojunction 35 of its associated semiconductor portion 3” means being electrically connected to the heterojunction 35 of the associated semiconductor portion 3 with no semiconductor layer interposed between the first electrode 4 and the first nitride semiconductor portion 31 or the second nitride semiconductor portion 32. In this embodiment, the first electrode 4 includes an alloy portion to make ohmic contact with the heterojunction 35 of the semiconductor portion 3 and a metallic portion on the alloy portion. In the semiconductor device 1A, the metallic portion of the first electrode 4 may include Ti and Al, for example, and the alloy portion may include Al, Ti, and Ga, for example. The alloy portion is formed to cover part of the first nitride semiconductor portion 31 and part of the second nitride semiconductor portion 32. Thus, the alloy portion overlaps with the first heterojunction 35 in the thickness direction D0.

In addition, in the semiconductor device 1A, the plurality of semiconductor portions 3 correspond one to one to the plurality of second electrodes 5. Each of the plurality of second electrodes 5 is provided on the semiconductor portion 3 at the other end thereof in the second direction D2. Each of the plurality of second electrodes 5 faces an associated one of the first electrodes 4 in the second direction D2. The plurality of second electrodes 5 are arranged in the first direction D1 to be spaced apart from each other. In the semiconductor device 1A, each of the plurality of second electrodes 5 is directly electrically connected to the heterojunction 35 of its associated semiconductor portion 3. As used herein, to be “electrically connected to” means making ohmic contact with. Also, as used herein, to be “directly electrically connected to the heterojunction 35 of its associated semiconductor portion 3” means being electrically connected to the heterojunction 35 of the associated semiconductor portion 3 with no semiconductor layer interposed between the second electrode 5 and the first nitride semiconductor portion 31 or the second nitride semiconductor portion 32. In this embodiment, the second electrode 5 includes an alloy portion to make ohmic contact with the heterojunction 35 of the semiconductor portion 3 and a metallic portion on the alloy portion. In the semiconductor device 1A, the metallic portion of the second electrode 5 may include Ti and Al, for example, and the alloy portion may include Al, Ti, and Ga, for example. The alloy portion is formed to cover part of the first nitride semiconductor portion 31 and part of the second nitride semiconductor portion 32. Thus, the alloy portion overlaps with the first heterojunction 35 in the thickness direction D0.

Furthermore, in the semiconductor device 1A, each of the plurality of gate electrodes 6 is formed on the surface 321, intersecting with the first direction D1, of the second nitride semiconductor portion 32. In the semiconductor device 1A, the plurality of semiconductor portions 3 correspond one to one to the plurality of gate electrodes 6. In addition, the plurality of gate electrodes 6 correspond one to one to the plurality of first electrodes 4. Furthermore, the plurality of gate electrodes 6 also correspond one to one to the plurality of second electrodes 5. Each of the plurality of gate electrodes 6 is arranged in the thickness direction D0. The plurality of gate electrodes 6 are arranged in the first direction D1 to be spaced apart from each other. Each of the plurality of gate electrodes 6 is separated in the second direction D2 from an associated one of the first electrodes 4 and an associated one of the second electrodes 5. The width as measured in the second direction D2 of each gate electrode 6 is shorter than the distance as measured in the second direction D2 between the first and second electrodes 4 and 5. In the semiconductor device 1A, the distance in the second direction D2 between the gate electrode 6 and the source electrode 4 is shorter than the distance in the second direction D2 between the gate electrode 6 and the drain electrode 5.

In the semiconductor device 1A, two adjacent ones of the plurality of gate electrodes 6 are connected together with an interconnect 61 formed on the fourth nitride semiconductor portion 34 of the semiconductor portion 3. Furthermore, in the semiconductor device 1A, the first common electrode 40 and the second common electrode 50 serve as a common source electrode and a common drain electrode, respectively.

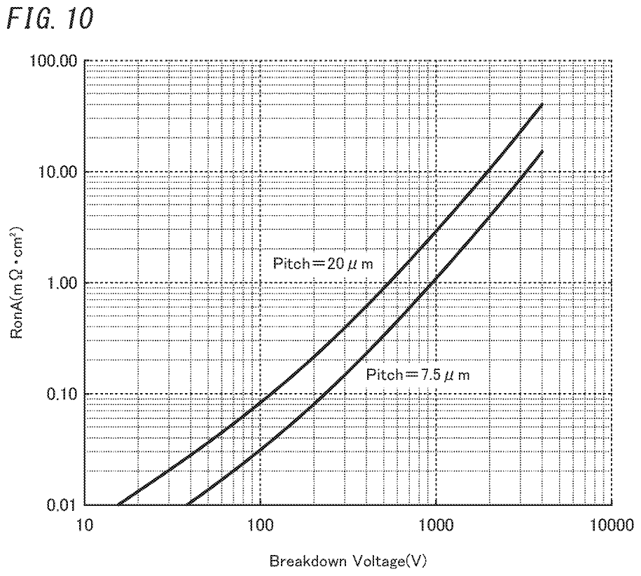

The semiconductor device 1A is able to increase the degree of integration of the plurality of semiconductor portions 3 and reduce the ON-state resistance of the semiconductor device 1A by shortening the pitch of the plurality of semiconductor portions 3 in the first direction D1 without changing the chip size of the semiconductor device 1A. FIG. 10 shows the results of simulation of ON-state resistance-breakdown voltage characteristics corresponding to two different pitches in the first direction D1 between the plurality of semiconductor portions 3 of the semiconductor device 1A. According to these simulations, the thickness as measured in the thickness direction D0 of the semiconductor portions 3 was supposed to be constant at 7.5 μm. As can be seen from FIG. 10, the ON-state resistance decreased when the pitch was 7.5 μm, compared to when the pitch was 20 μm.

Furthermore, with an eye to increasing the degree of integration of the plurality of semiconductor portions 3 in the semiconductor device 1A, the surface 321 intersecting with the first direction D1 of the second nitride semiconductor portion 32 suitably has a taper angle θ falling within the range from 70 degrees to 100 degrees, more suitably has a taper angle θ falling within the range from 80 degrees to 95 degrees, and even more suitably has a taper angle θ of approximately 90 degrees. From the viewpoint of curbing a decrease in the concentration of the two-dimensional electron gas 37 produced in each of the plurality of semiconductor portions 3, the semiconductor device 1A suitably has a taper angle θ equal to or greater than 70 degrees. FIGS. 3 and 4, already referred to in the description of the first embodiment, show the results of simulations of relationship between the taper angle θ and the concentration of the two-dimensional electron gas of the semiconductor portions 3. Specifically, FIG. 3 shows the results of simulations obtained when the undoped AlGaN crystals forming the second nitride semiconductor portion 32 had an Al composition ratio (i.e., the mole fraction x in AlₓGa₁₋ₓN) of 0.25. Also, in FIG. 4, the solid curve represents the result of simulations obtained when the undoped AlGaN crystals forming the second nitride semiconductor portion 32 had an Al composition ratio of 0.25. That is to say, this portion of FIG. 4 is a partially enlarged one of FIG. 3. Meanwhile, in FIG. 4, the one-dot-chain curve represents the result of simulations obtained when the undoped AlGaN crystals forming the second nitride semiconductor portion 32 had an Al composition ratio of 0.20. Furthermore, in FIG. 4, the two-dot-chain curve represents the result of simulations obtained when the undoped AlGaN crystals forming the second nitride semiconductor portion 32 had an Al composition ratio of 0.15. As can be seen from FIGS. 3 and 4, setting the taper angle at 70 degrees or more curbs a decrease in the concentration of the two-dimensional electron gas.

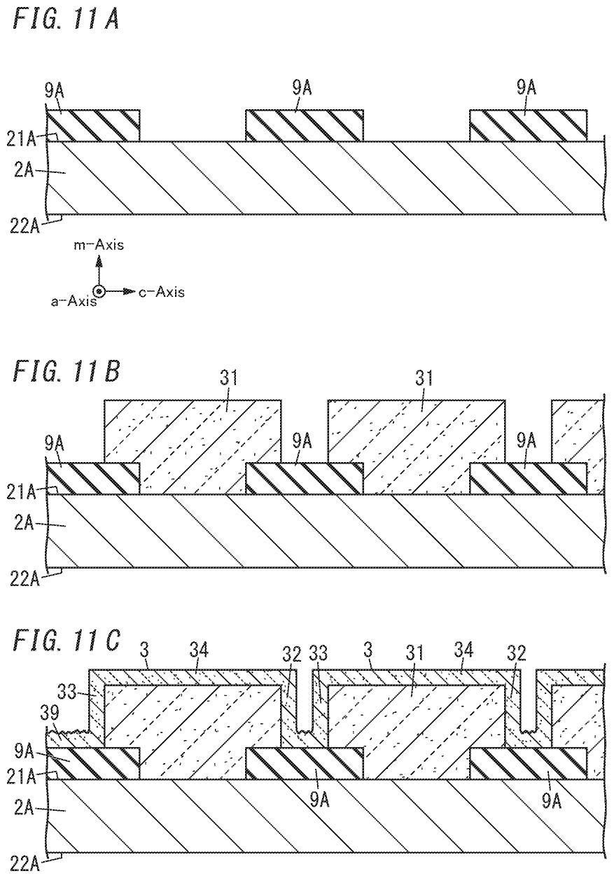

An exemplary method for fabricating the semiconductor device 1A will be described briefly with reference to FIGS. 11A-11C, FIGS. 12A-12C, FIGS. 13A-13C, and FIGS. 14A-14C.

According to a method for fabricating the semiconductor device 1A, an insulator portion forming step, a first epitaxial growth process, and a second epitaxial growth step are performed in this order to form a plurality of semiconductor portions 3. According to this method for fabricating the semiconductor device 1A, after the second epitaxial growth step has been performed, a poly-crystal removing step, a first electrode and second electrode forming step, and a gate electrode forming step are performed in this order.

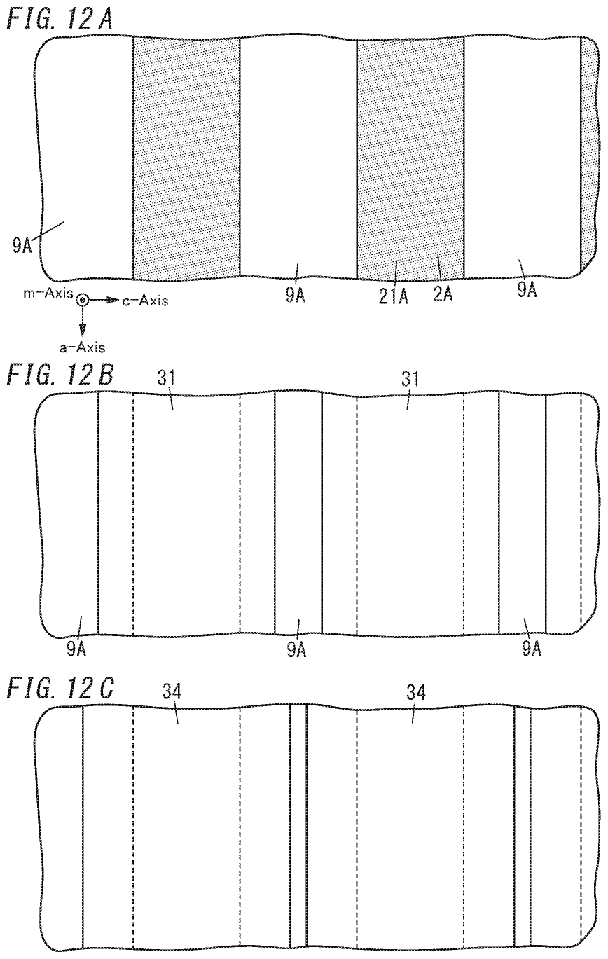

The insulator portion forming step includes forming a plurality of insulator portions 9A, extending linearly and arranged in a direction aligned with a c-axis of the nitride semiconductor substrate 2A, on the first surface 21A of the nitride semiconductor substrate 2A (see FIGS. 11A and 12A). A material for the insulator portions 9A may be silicon dioxide, for example. The insulator portion forming step includes forming a plurality of insulator portions 9A simultaneously by, for example, a thin film forming technique, a photolithographic technique, and an etching technique in combination.

The first epitaxial growth step includes forming a plurality of first nitride semiconductor portions 31 by epitaxial lateral overgrowth (ELO). Each of the plurality of first nitride semiconductor portions 31 covers a region between two adjacent ones of the plurality of insulator portions 9A on the first surface 21A of the nitride semiconductor substrate 2A and respective surface portions of the two adjacent insulator portions 9A (see FIGS. 11B and 12B). The ELO is a crystal-growing technique that adopts selective growth and lateral growth in combination. Specifically, a portion, designed to be formed directly on the first surface 21A of the nitride semiconductor substrate 2A, of the first nitride semiconductor portion 31 is formed by selective growth, while a portion thereof designed to be formed on the insulator portions 9A is formed by lateral growth. In the first epitaxial growth step, a metalorganic vapor phase epitaxy (MOVPE) system is used as an epitaxial growth system. In the first epitaxial growth step, trimethylgallium (TMGa), for example, may be used as a Ga source gas and NH₃, for example, may be used as an N source gas. A carrier gas for the respective source gases may be an H₂ gas, an N₂ gas, or a mixture of an H₂ gas and an N₂ gas, for example. As for conditions for growing the first nitride semiconductor portion 31, substrate temperature, V/III ratio, flow rates of the respective source gases, growth pressures, and other parameters may be set appropriately. As used herein, the “V/III ratio” refers to the ratio of the molar flow rate [μmol/min] of a source gas of a Group V element to the molar flow rate [μmol/min] of a source gas of a Group III element. The “growth pressure” refers herein to the pressure in the reaction furnace in a state where the respective source gases and carrier gases are being supplied into the reaction furnace of the MOVPE system.

The second epitaxial growth step includes epitaxially growing a plurality of second nitride semiconductor portions 32 on an associated one of the plurality of first nitride semiconductor portions 31 (see FIGS. 11C and 12C). In the second epitaxial growth step, a metalorganic vapor phase epitaxy (MOVPE) system is used as an epitaxial growth system. The second epitaxial growth step is performed continuously with the first epitaxial growth step in the MOVPE system in which the first epitaxial growth step has been performed. In the second epitaxial growth step, trimethylaluminum (TMA1), for example, may be used as an Al source gas, trimethylgallium (TMGa), for example, may be used as a Ga source gas, and NH₃, for example, may be used as an N source gas. A carrier gas for the respective source gases may be an H₂ gas, an N₂ gas, or a mixture of an H₂ gas and an N₂ gas, for example. As for conditions for growing the second nitride semiconductor portion 32, substrate temperature, V/III ratio, flow rates of the respective source gases, growth pressures, and other parameters may be set appropriately. As used herein, the “V/III ratio” refers to the ratio of the molar flow rate [μmol/min] of a source gas of a Group V element to the molar flow rate [μmol/min] of a source gas of a Group III element.

According to the method for fabricating the semiconductor device 1A, in the second epitaxial growth step, while a plurality of second nitride semiconductor portions 32, corresponding one to one to a plurality of first nitride semiconductor portions 31, are epitaxially grown on the plurality of first nitride semiconductor portions 31, a plurality of third nitride semiconductor portions 33 and a plurality of fourth nitride semiconductor portions 34 are epitaxially grown on the plurality of first nitride semiconductor portions 31 and polycrystalline AlGaN 39 is deposited on a plurality of insulator portions 9A. While the plurality of second nitride semiconductor portions 32 are epitaxially grown on the plurality of first nitride semiconductor portions 31, the polycrystalline AlGaN 39 is deposited on each insulator portion 9A.

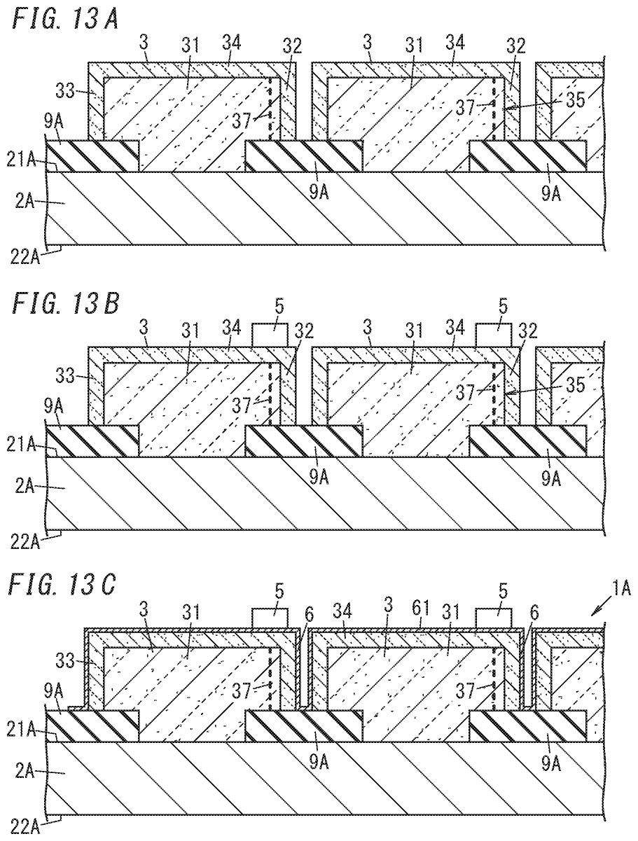

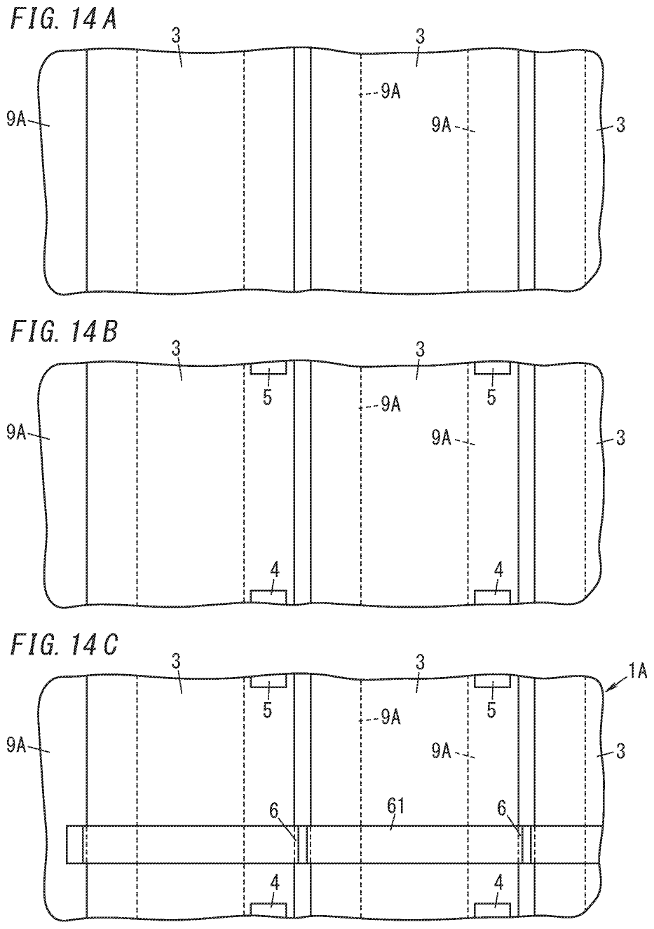

The poly-crystal removing step includes etching and thereby removing the polycrystalline AlGaN 39 formed on each of the plurality of insulator portions 9A (see FIGS. 13A and 14A). In the poly-crystal removing step, the polycrystalline AlGaN may be selectively etched with a tetra-methyl-ammonium hydroxide (TMAH) solution, for example. Setting the temperature of the TMAH solution at around 80° C. allows the etch time to be shortened compared to setting the temperature of the TMAH solution at room temperature.

The first electrode and second electrode forming step includes forming a metallic portion on each of the regions where the first electrodes 4 and the second electrodes 5 are going to be formed on each of the plurality of semiconductor portions 3, and then forming an alloy portion through sintering to form the first electrodes 4 and second electrodes 5, each including a metallic portion and an alloy portion (see FIGS. 13B and 14B). The first electrode and second electrode forming step includes forming the alloy portion by causing, through sintering, the metal in the metallic portion to diffuse toward a portion, located right under the metallic portion, of each of the fourth nitride semiconductor portions 34. Optionally, the first electrode and second electrode forming step may include forming a first common electrode 40 and a second common electrode 50.

The gate electrode forming step includes forming a plurality of gate electrodes 6 by thin film forming technique (see FIGS. 13C and 14C). The gate electrode forming step may include forming interconnects 61 along with the plurality of gate electrodes 6.

According to the method for fabricating the semiconductor device 1A, a wafer, from which a plurality of semiconductor devices 1A are formed, may be obtained by using a wafer that forms the basis of the nitride semiconductor substrates 2A until the gate electrode forming step is finished. According to the method for fabricating the semiconductor device 1A, a plurality of semiconductor devices 1A may be obtained by cutting off, with a dicing saw, for example, the wafer on which a plurality of semiconductor devices 1A have been formed.

The semiconductor device 1A according to the second embodiment described above contributes to reducing the electrical resistance between the first common electrode 40 and the second common electrode 50. More specifically, the semiconductor device 1A according to the second embodiment contributes to reducing the ON-state resistance. In this case, the semiconductor device 1A contributes to reducing the ON-state resistance while increasing the breakdown voltage. The longer the distance between the first electrode 4 and the second electrode 5 in the second direction D2 is, the more significantly the semiconductor device 1A may increase the breakdown voltage.

The larger the number of the first heterojunctions 35 is, the more significantly the semiconductor device 1A may reduce the electrical resistance. Thus, RonA (which is ON-state resistance per unit area and of which the unit is Ω·cm²) of the semiconductor device 1A may be reduced by increasing the number of the first heterojunctions 35 with the interval between the first heterojunctions 35 adjacent to each other in the first direction D1 shortened. As used herein, RonA is the product of Ron (i.e., the ON-state resistance (a)) and the area of the semiconductor device 1A (which is the chip area of the semiconductor device 1A in a plan view and which may be 1 cm×1 cm=1 cm², for example).

In addition, as the length of the first heterojunction 35 as measured in the thickness direction D0 perpendicular to both the first direction D1 and the second direction D2 is increased, the semiconductor device 1A may reduce RonA even more significantly.

The semiconductor device 1A may determine its breakdown voltage by the gate-drain distance that is the distance between the gate electrode 6 and the drain electrode 5, and may also determine the resistance (i.e., ON-state resistance) by the drain-source distance that is the distance between the drain electrode 5 and the source electrode 4. The ON-state resistance depends on not only the drain-source distance but also the length of the first heterojunction 35 as measured in the thickness direction D0 defined for the nitride semiconductor substrate 2A, for example.

### Advantages

A semiconductor device 1A according to the second embodiment includes a nitride semiconductor substrate 2A, a plurality of insulator portions 9A, a plurality of semiconductor portions 3, a plurality of first electrodes 4, a plurality of second electrodes 5, a first common electrode 40, and a second common electrode 50. The nitride semiconductor substrate 2A has a first surface 21A and a second surface 22A located opposite from each other in a thickness direction D0. The first surface 21A of the nitride semiconductor substrate 2A is a crystallographic plane aligned with a c-axis. Each of the plurality of insulator portions 9A is elongated linearly in a second direction D2 perpendicular to both the thickness direction D0 defined for the nitride semiconductor substrate 2A and a first direction D1 aligned with the c-axis of the nitride semiconductor substrate 2A. The plurality of insulator portions 9A are arranged side by side in the first direction D1 on the first surface 21A of the nitride semiconductor substrate 2A. The plurality of semiconductor portions 3 are arranged in the first direction D1 to be spaced apart from each other. Each of the plurality of semiconductor portions 3 includes a first nitride semiconductor portion 31 and a second nitride semiconductor portion 32. The first nitride semiconductor portion 31 is formed on a region between two adjacent ones of the plurality of insulator portions 9A on the first surface 21A of the nitride semiconductor substrate 2A and extends over the two adjacent insulator portions 9A. The second nitride semiconductor portion 32 is directly formed on one surface 311, aligned with a +c plane, out of two surfaces 311, 312 intersecting with the first direction D1 in the first nitride semiconductor portion 31. Each of the plurality of first electrodes 4 is electrically connected to a heterojunction 35 between the first nitride semiconductor portion 31 and the second nitride semiconductor portion 32 of an associated one of the plurality of semiconductor portions 3. Each of the plurality of second electrodes 5 is electrically connected to the heterojunction 35 between the first nitride semiconductor portion 31 and the second nitride semiconductor portion 32 of an associated one of the plurality of semiconductor portions 3. Each of the plurality of second electrodes 5 is spaced in the second direction D2 from an associated one of the plurality of first electrodes 4. The plurality of first electrodes 4 are electrically connected in common to the first common electrode 40. The plurality of second electrodes 5 are electrically connected in common to the second common electrode 50.

The semiconductor device 1A according to the second embodiment contributes to reducing the electrical resistance.

### Variations of Second Embodiment

Note that the second embodiment described above is only an exemplary one of various embodiments of the present disclosure and should not be construed as limiting. Rather, the second exemplary embodiment may be readily modified in various manners depending on a design choice or any other factor without departing from the scope of the present disclosure.

For example, a semiconductor device 1A according to a first variation of the second embodiment may further include a plurality of gate layers. Each of the plurality of gate layers is interposed, in the first direction D1, between an associated one of the gate electrodes 6 and an associated one of the semiconductor portions 3. More specifically, each of the plurality of gate layers is interposed, in the first direction D1, between the associated gate electrode 6 and an associated one of the second nitride semiconductor portions 32. Each of the plurality of gate layers forms a depletion layer between the associated second nitride semiconductor portion 32 and an associated one of the first nitride semiconductor portions 31. Each of the plurality of gate layers forms a depletion layer in the associated semiconductor portions 3 when no voltage is applied between an associated one of the gate electrodes 6 and an associated one of the source electrodes 4 or between an associated one of the drain electrodes 5 and the associated source electrode 4. Thus, this first variation provides a normally OFF field-effect transistor. According to the first variation, when voltage to turn the semiconductor device 1A ON is applied between the associated gate electrode 6 and the associated source electrode 4 and voltage is applied between the associated drain electrode 5 and the associated source electrode 4, the associated source electrode 4 and drain electrode 5 may be connected together with the two-dimensional electron gas 37. In other words, this first variation prevents the two-dimensional electron gas 37 from being interrupted by the depletion layer halfway between the source electrode 4 and drain electrode 5 that face each other in the second direction D2.

Each of the plurality of gate layers may be a p-type semiconductor layer, for example. In this embodiment, the p-type semiconductor layer may be a metal oxide layer, for example. A metal oxide layer serving as the p-type semiconductor layer may be an NiO layer, for example. Optionally, the NiO layer may contain, as an impurity, at least one alkali metal selected from the group consisting of lithium (Li), sodium (Na), potassium (K), rubidium (Rb), and cesium (Cs). The NiO layer may also contain, for example, a transition metal such as silver (Ag) or copper (Cu) which becomes univalent when added as an impurity. When measured in the first direction D1, the thickness of each gate layer may be 100 nm, for example. Note that each gate layer has only to be a p-type semiconductor layer and does not have to be an NiO layer but may also be a p-type AlGaN layer or a p-type GaN layer, for example.

Meanwhile, a semiconductor device 1A according to a second variation of the second embodiment does not include the gate electrode 6 of the semiconductor device 1A according to the second embodiment. According to the second variation, as in the semiconductor device 1A according to the second embodiment, a plurality of double heterostructures 30 are arranged side by side in the first direction D1, and therefore, undoped AlGaN crystals and undoped GaN crystals are arranged alternately in the first direction D1. Thus, according to the second variation, a plurality of two-dimensional electron gases 37 and a plurality of two-dimensional hole gases are arranged alternately in the first direction D1. Furthermore, according to the second variation, the width as measured in the first direction D1 of each first electrode 4 is approximately equal to the width as measured in the first direction D1 of its associated semiconductor portion 3, and the first electrode 4 is directly electrically connected to the first heterojunction 35 and the second heterojunction 36. Furthermore, according to the second variation, the width as measured in the first direction D1 of each second electrode 5 is approximately equal to the width as measured in the first direction D1 of its associated semiconductor portion 3, and each second electrode 5 is directly electrically connected to the first heterojunction 35 and the second heterojunction 36. In this case, according to the second variation, a Schottky barrier diode is formed. Furthermore, according to the second variation, with respect to the two-dimensional electron gas 37, either the first electrode 4 or the second electrode 5 is formed of a metal with a relatively large work function (i.e., a metal to form a p-electrode) without sintering and electrically connected. With respect to a two-dimensional hole gas, on the other hand, either the first electrode 4 or the second electrode 5 is formed of a metal with a relatively small work function (i.e., a metal to form an n-electrode) with sintering. Furthermore, according to the second variation, one of the first electrode 4 or the second electrode 5 constitutes an anode electrode, while the other constitutes a cathode electrode. According to the second variation, either the first electrode 4 or the second electrode 5 having the higher potential when voltage is applied between the first electrode 4 and the second electrode 5 constitutes the anode electrode and either the first electrode 4 or the second electrode 5 having the lower potential when voltage is applied between the first electrode 4 and the second electrode 5 constitutes the cathode electrode. The second variation is implemented as a multi-channel diode.

Furthermore, according to the second variation, in each of the plurality of double heterostructures 30, the third nitride semiconductor portion 33, the first nitride semiconductor portion 31, and the second nitride semiconductor portion 32 are arranged in this order in the first direction D1. Each of the plurality of double heterostructures 30 includes a first heterojunction 35 as a heterojunction between the first nitride semiconductor portion 31 and the second nitride semiconductor portion 32 and a second heterojunction 36 as a heterojunction between the first nitride semiconductor portion 31 and the third nitride semiconductor portion 33. According to the second variation, one of the first electrode 4 or the second electrode 5 constitutes an anode electrode and the other constitutes a cathode electrode. Thus, this second variation provides a diode contributing to reducing the electrical resistance while increasing the breakdown voltage.

Furthermore, in the semiconductor device 1A described above, the first electrode 4 and the second electrode 5 serve as a source electrode and a drain electrode, respectively. However, this is only an example of the present disclosure and should not be construed as limiting. Alternatively, the first electrode 4 and the second electrode 5 may serve as a drain electrode and a source electrode, respectively.

Furthermore, the nitride semiconductor substrate 2A does not have to be a GaN substrate but may also be an AlN substrate, for example.

Furthermore, in the embodiment described above, the plurality of semiconductor portions 3 are arranged at regular intervals in the first direction D1. However, the plurality of semiconductor portions 3 do not have to be arranged at regular intervals.

Optionally, the semiconductor device 1A may include a plurality of passivation portions, each of which is provided between two adjacent ones of the plurality of semiconductor portions 3 to cover the gate electrode 6 arranged between the two semiconductor portions 3. Each of the plurality of passivation portions has electrical insulation properties. Each of the plurality of passivation portions may be made of silicon dioxide, for example. However, this is only an example of the present disclosure and should not be construed as limiting. Alternatively, each of the plurality of passivation portions may also be made of silicon nitride, for example.

Furthermore, the epitaxial growth process to form the first nitride semiconductor portion 31 does not have to be MOVPE but may also be hydride vapor phase epitaxy (HVPE). Likewise, the epitaxial growth process to form the second nitride semiconductor portion 32, the third nitride semiconductor portion 33, and the fourth nitride semiconductor portion 34 does not have to be MOVPE but may also be HVPE. The undoped GaN crystals and the undoped AlGaN crystals may include Mg, H, Si, C, O, and other impurities to be inevitably contained during their growth.

### Resume

The embodiments and their variations described above are implementations of the following aspects of the present disclosure.

A semiconductor device (1) according to a first aspect includes a plurality of semiconductor portions (3), a plurality of first electrodes (4), a plurality of second electrodes (5), a first common electrode (40), and a second common electrode (50). The plurality of semiconductor portions (3) are arranged in a first direction (D1) to be spaced apart from each other. Each of the plurality of semiconductor portions (3) has a heterojunction (35) between a first nitride semiconductor portion (31) and a second nitride semiconductor portion (32) having a larger bandgap than the first nitride semiconductor portion (31). The heterojunction (35) of each of the plurality of semiconductor portions (3) extends in a second direction (D2) perpendicular to a first direction (D1) aligned with a c-axis of the first nitride semiconductor portion (31). Each of the plurality of first electrodes (4) overlaps with an associated one of the plurality of semiconductor portions (3) in a third direction (D3) perpendicular to both of the first direction (D1) and the second direction (D2). Each of the plurality of first electrodes (4) is directly electrically connected to the heterojunction (35) of the associated semiconductor portion (3). Each of the plurality of second electrodes (5) forms a pair of first and second electrodes (4, 5) with one of the plurality of first electrodes (4) and is located, with respect to an associated one of the plurality of semiconductor portions (3), opposite in the third direction (D3) from the one of the plurality of first electrodes (4) that overlaps with the associated semiconductor portion (3) such that the associated semiconductor portion (3) is sandwiched in the third direction (D3) between the pair of first and second electrodes (4, 5). Each of the plurality of second electrodes (5) is directly electrically connected to the heterojunction (35) of the associated semiconductor portion (3). The plurality of first electrodes (4) are electrically connected in common to the first common electrode (40). The plurality of second electrodes (5) are electrically connected in common to the second common electrode (50).

A semiconductor device (1) according to the first aspect contributes to reducing electrical resistance.

A semiconductor device (1) according to a second aspect, which may be implemented in conjunction with the first aspect, further includes a substrate (2). The substrate (2) has a first surface (21) and a second surface (22) located opposite from each other in the third direction (D3). The plurality of second electrodes (5) are arranged on the first surface (21) of the substrate (2).

In a semiconductor device (1) according to a third aspect, which may be implemented in conjunction with the second aspect, the substrate (2) is a nitride semiconductor substrate. The first surface (21) is a crystallographic plane aligned with a c-axis of the nitride semiconductor substrate.

In a semiconductor device (1) according to a fourth aspect, which may be implemented in conjunction with the third aspect, the first nitride semiconductor portion (31) is an epitaxial layer underlain by the nitride semiconductor substrate (substrate 2). The second nitride semiconductor portion (32) is an epitaxial layer underlain by the first nitride semiconductor portion (31).

In a semiconductor device (1) according to a fifth aspect, which may be implemented in conjunction with the third or fourth aspect, each of the plurality of second electrodes (5) extends linearly in the second direction (D2). The plurality of second electrodes (5) are arranged on the first surface (21) of the substrate (2) to be spaced apart from each other in the first direction (D1).

A semiconductor device (1) according to the fifth aspect contributes to further reducing the electrical resistance.

In a semiconductor device (1) according to a sixth aspect, which may be implemented in conjunction with any one of the second to fifth aspects, in each of the plurality of semiconductor portions (3), an interior angle formed between a surface (321), intersecting with the first direction (D1), of the second nitride semiconductor portion (32) and a surface, parallel to the first surface (21), of one of the plurality of second electrodes (5) that is directly electrically connected to the heterojunction (35) of the associated semiconductor portion (3) is 70 degrees or more.

A semiconductor device (1) according to a sixth aspect is able to curb a decrease in the concentration of a two-dimensional electron gas produced in the vicinity of the heterojunction (35).

A semiconductor device (1) according to a seventh aspect, which may be implemented in conjunction with any one of the first to sixth aspects, further includes a plurality of gate electrodes (6). Each of the plurality of gate electrodes (6) faces, in the first direction (D1), the second nitride semiconductor portion (32) of an associated one of the plurality of semiconductor portions (3).

A semiconductor device (1) according to a seventh aspect may be implemented as a field-effect transistor and contributes to reducing the ON-state resistance of the field-effect transistor.

A method for fabricating a semiconductor device according to an eighth aspect is a method for fabricating the semiconductor device (1) according to the fifth aspect. The method includes a mask portion forming step, a first epitaxial growth step, and a second epitaxial growth step. The mask portion forming step includes forming a plurality of mask portions (9) each extending linearly on the first surface (21) of the substrate (2). The plurality of mask portions (9) are arranged along a c-axis of the substrate (2). The first epitaxial growth step includes forming a plurality of the first nitride semiconductor portions (31) by ELO. Each of the plurality of the first nitride semiconductor portions (31) covers a region between two adjacent ones of the plurality of mask portions (9) on the first surface (21) of the substrate (2) and respective surface portions of the two adjacent mask portions (9). The second epitaxial growth step includes epitaxially growing a plurality of the second nitride semiconductor portions (32) on an associated one of the plurality of the first nitride semiconductor portions (31).

A method for fabricating a semiconductor device according to the eighth aspect provides a semiconductor device (1) contributing to reducing the electrical resistance.

A semiconductor device (1A) according to a ninth aspect includes a nitride semiconductor substrate (2A), a plurality of insulator portions (9A), a plurality of semiconductor portions (3), a plurality of first electrodes (4), a plurality of second electrodes (5), a first common electrode (40), and a second common electrode (50). The nitride semiconductor substrate (2A) has a first surface (21A) and a second surface (22A) located opposite from each other in a thickness direction (D0). The first surface (21A) of the nitride semiconductor substrate (2A) is a crystallographic plane aligned with a c-axis. Each of the plurality of insulator portions (9A) is elongated linearly in a second direction (D2) perpendicular to both the thickness direction (D0) defined for the nitride semiconductor substrate (2A) and a first direction (D1) aligned with the c-axis of the nitride semiconductor substrate (2A). The plurality of insulator portions (9A) are arranged side by side in the first direction (D1) on the first surface (21A) of the nitride semiconductor substrate (2A). The plurality of semiconductor portions (3) are arranged in the first direction (D1) to be spaced apart from each other. Each of the plurality of semiconductor portions (3) includes a first nitride semiconductor portion (31) and a second nitride semiconductor portion (32). The first nitride semiconductor portion (31) is formed on a region between two adjacent ones of the plurality of insulator portions (9A) on the first surface (21A) of the nitride semiconductor substrate (2A) and extends over the two adjacent insulator portions (9A). The second nitride semiconductor portion (32) is directly formed on one surface (311), aligned with a +c plane, out of two surfaces (311, 312) intersecting with the first direction (D1) in the first nitride semiconductor portion (31). Each of the plurality of first electrodes (4) is electrically connected to a heterojunction (35) between the first nitride semiconductor portion (31) and the second nitride semiconductor portion (32) of an associated one of the plurality of semiconductor portions (3). Each of the plurality of second electrodes (5) is electrically connected to the heterojunction (35) between the first nitride semiconductor portion (31) and the second nitride semiconductor portion (32) of an associated one of the plurality of semiconductor portions (3). Each of the plurality of second electrodes (5) is spaced in the second direction (D2) from an associated one of the plurality of first electrodes (4). The plurality of first electrodes (4) are electrically connected in common to the first common electrode (40). The plurality of second electrodes (5) are electrically connected in common to the second common electrode (50).

A semiconductor device (1A) according to the ninth aspect contributes to reducing the electrical resistance. This allows the semiconductor device (1A) according to the ninth aspect to reduce the loss as well.

In a semiconductor device (1A) according to a tenth aspect, which may be implemented in conjunction with the ninth aspect, each of the plurality of first electrodes (4) is an upper electrode formed on the associated semiconductor portion (3) in the thickness direction (D0). Each of the plurality of second electrodes (5) is an upper electrode formed on the associated semiconductor portion (3) in the thickness direction (D0).

A semiconductor device (1A) according to the tenth aspect allows the plurality of first electrodes (4) and the plurality of second electrodes (5) to be formed easily during its manufacturing process.

In a semiconductor device (1A) according to an eleventh aspect, which may be implemented in conjunction with the ninth or tenth aspect, in each of the plurality of semiconductor portions (3), an interior angle formed between a surface (321), intersecting with the first direction (D1), of the second nitride semiconductor portion (32) and a surface, parallel to the first surface (21A) of the nitride semiconductor substrate (2A), of one of the plurality of insulator portions (9A) that is in contact with the second nitride semiconductor portion (32) is 70 degrees or more.

A semiconductor device (1A) according to the eleventh aspect is able to curb a decrease in the concentration of a two-dimensional electron gas (37) produced in the vicinity of the heterojunction (35).

In a semiconductor device (1A) according to a twelfth aspect, which may be implemented in conjunction with the eleventh aspect, the first nitride semiconductor portion (31) is an epitaxial layer underlain by the nitride semiconductor substrate (2A). The second nitride semiconductor portion (32) is an epitaxial layer underlain by the first nitride semiconductor portion (31).

A semiconductor device (1A) according to a thirteenth aspect, which may be implemented in conjunction with any one of the ninth to twelfth aspects, further includes a plurality of gate electrodes (6). Each of the plurality of gate electrodes (6) faces, in the first direction (D1), the second nitride semiconductor portion (32) of an associated one of the plurality of semiconductor portions (3).

A semiconductor device (1A) according to the thirteenth aspect contributes to increasing the breakdown voltage and reducing the electrical resistance.

A method for fabricating a semiconductor device according to a fourteenth aspect is a method for fabricating the semiconductor device (1A) according to the ninth aspect. The method includes an insulator portion forming step, a first epitaxial growth step, and a second epitaxial growth step. The insulator portion forming step includes forming the plurality of insulator portions (9A) on the first surface (21A) of the nitride semiconductor substrate (2A). The first epitaxial growth step includes forming the plurality of the first nitride semiconductor portions (31) by ELO. The second epitaxial growth step includes epitaxially growing the second nitride semiconductor portion (32) on each of the plurality of the first nitride semiconductor portions (31).

A method for fabricating a semiconductor device according to the fourteenth aspect provides a semiconductor device (1A) contributing to reducing the electrical resistance.

### REFERENCE SIGNS LIST

1 Semiconductor Device

1A Semiconductor Device

2 Substrate

21 First Surface

22 Second Surface

2A Nitride Semiconductor Substrate

21A First Surface

22A Second Surface

3 Semiconductor Portion

31 First Nitride Semiconductor Portion

311 Surface (First Surface)

312 Surface (Second Surface)

32 Second Nitride Semiconductor Portion

321 Surface

35 Heterojunction

4 First Electrode

5 Second Electrode

6 Gate Electrode

6 Third Electrode (Gate Electrode)

9 Mask Portion

9A Insulator Portion

40 First Common Electrode

50 Second Common Electrode

D0 Thickness Direction

D1 First Direction

D2 Second Direction

D3 Third Direction

1. A semiconductor device comprising:
a plurality of semiconductor portions arranged in a first direction to be spaced apart from each other, each of the plurality of semiconductor portions having a heterojunction between a first nitride semiconductor portion and a second nitride semiconductor portion having a larger bandgap than the first nitride semiconductor portion, the heterojunction extending in a second direction perpendicular to a first direction aligned with a c-axis of the first nitride semiconductor portion;
a plurality of first electrodes, each of the plurality of first electrodes overlapping with an associated one of the plurality of semiconductor portions in a third direction perpendicular to both of the first direction and the second direction, each of the plurality of first electrodes being directly electrically connected to the heterojunction of the associated semiconductor portion;
a plurality of second electrodes, each of the plurality of second electrodes forming a pair of first and second electrodes with one of the plurality of first electrodes and being located, with respect to an associated one of the plurality of semiconductor portions, opposite in the third direction from the one of the plurality of first electrodes that overlaps with the associated semiconductor portion such that the associated semiconductor portion is sandwiched in the third direction between the pair of first and second electrodes, each of the plurality of second electrodes being directly electrically connected to the heterojunction of the associated semiconductor portion;
a first common electrode to which the plurality of first electrodes are electrically connected in common; and
a second common electrode to which the plurality of second electrodes are electrically connected in common.

2. The semiconductor device of claim 1, further comprising a substrate having a first surface and a second surface located opposite from each other in the third direction, wherein
the plurality of second electrodes are arranged on the first surface of the substrate.

3. The semiconductor device of claim 2, wherein
the substrate is a nitride semiconductor substrate, and
the first surface is a crystallographic plane aligned with a c-axis of the nitride semiconductor substrate.

4. The semiconductor device of claim 3, wherein
the first nitride semiconductor portion is an epitaxial layer underlain by the nitride semiconductor substrate, and
the second nitride semiconductor portion is an epitaxial layer underlain by the first nitride semiconductor portion.

5. The semiconductor device of claim 3, wherein
each of the plurality of second electrodes extends linearly in the second direction, and
the plurality of second electrodes are arranged on the first surface of the substrate to be spaced apart from each other in the first direction.

6. The semiconductor device of claim 2, wherein
in each of the plurality of semiconductor portions, an interior angle formed between a surface, intersecting with the first direction, of the second nitride semiconductor portion and a surface, parallel to the first surface, of one of the plurality of second electrodes that is directly electrically connected to the heterojunction of the associated semiconductor portion is 70 degrees or more.

7. The semiconductor device of claim 1, further comprising a plurality of gate electrodes, each of the plurality of gate electrodes facing, in the first direction, the second nitride semiconductor portion of an associated one of the plurality of semiconductor portions.

8. A method for fabricating the semiconductor device of claim 5, the method comprising:
a mask portion forming step including forming a plurality of mask portions each extending linearly on the first surface of the substrate, the plurality of mask portions being arranged along a c-axis of the substrate;
a first epitaxial growth step including forming a plurality of the first nitride semiconductor portions by ELO, each of the plurality of the first nitride semiconductor portions covering a region between two adjacent ones of the plurality of mask portions on the first surface of the substrate and respective surface portions of the two adjacent mask portions; and
a second epitaxial growth step including epitaxially growing a plurality of the second nitride semiconductor portions on an associated one of the plurality of the first nitride semiconductor portions.

9. A semiconductor device comprising:
a nitride semiconductor substrate having a first surface and a second surface located opposite from each other in a thickness direction, the first surface being a crystallographic plane aligned with a c-axis;
a plurality of insulator portions, each of the plurality of insulator portions being elongated linearly in a second direction perpendicular to both the thickness direction and a first direction aligned with the c-axis of the nitride semiconductor substrate, the plurality of insulator portions being arranged side by side in the first direction on the first surface of the nitride semiconductor substrate;
a plurality of semiconductor portions arranged in the first direction to be spaced apart from each other, each of the plurality of semiconductor portions including a first nitride semiconductor portion and a second nitride semiconductor portion, the first nitride semiconductor portion being formed on a region between two adjacent ones of the plurality of insulator portions on the first surface of the nitride semiconductor substrate and extending over the two adjacent insulator portions, the second nitride semiconductor portion being directly formed on one surface, aligned with a +c plane, out of two surfaces intersecting with the first direction in the first nitride semiconductor portion;
a plurality of first electrodes, each of the plurality of first electrodes being electrically connected to a heterojunction between the first nitride semiconductor portion and the second nitride semiconductor portion of an associated one of the plurality of semiconductor portions;
a plurality of second electrodes, each of the plurality of second electrodes being electrically connected to the heterojunction between the first nitride semiconductor portion and the second nitride semiconductor portion of an associated one of the plurality of semiconductor portions, each of the plurality of second electrodes being spaced in the second direction from an associated one of the plurality of first electrodes;
a first common electrode to which the plurality of first electrodes are electrically connected in common; and
a second common electrode to which the plurality of second electrodes are electrically connected in common.

10. The semiconductor device of claim 9, wherein
each of the plurality of first electrodes is an upper electrode formed on the associated semiconductor portion in the thickness direction, and
each of the plurality of second electrodes is an upper electrode formed on the associated semiconductor portion in the thickness direction.

11. The semiconductor device of claim 9, wherein
in each of the plurality of semiconductor portions, an interior angle formed between a surface, intersecting with the first direction, of the second nitride semiconductor portion and a surface, parallel to the first surface of the nitride semiconductor substrate, of one of the plurality of insulator portions that is in contact with the second nitride semiconductor portion is 70 degrees or more.

12. The semiconductor device of claim 11, wherein
the first nitride semiconductor portion is an epitaxial layer underlain by the nitride semiconductor substrate, and
the second nitride semiconductor portion is an epitaxial layer underlain by the first nitride semiconductor portion.

13. The semiconductor device of claim 9, further comprising a plurality of gate electrodes, each of the plurality of gate electrodes facing, in the first direction, the second nitride semiconductor portion of an associated one of the plurality of semiconductor portions.

14. A method for fabricating the semiconductor device of claim 9, the method comprising:
an insulator portion forming step including forming the plurality of insulator portions on the first surface of the nitride semiconductor substrate;
a first epitaxial growth step including forming the plurality of the first nitride semiconductor portions by ELO; and
a second epitaxial growth step including epitaxially growing the second nitride semiconductor portion on each of the plurality of the first nitride semiconductor portions.

15. The semiconductor device of claim 4, wherein
each of the plurality of second electrodes extends linearly in the second direction, and
the plurality of second electrodes are arranged on the first surface of the substrate to be spaced apart from each other in the first direction.

16. The semiconductor device of claim 3, wherein
in each of the plurality of semiconductor portions, an interior angle formed between a surface, intersecting with the first direction, of the second nitride semiconductor portion and a surface, parallel to the first surface, of one of the plurality of second electrodes that is directly electrically connected to the heterojunction of the associated semiconductor portion is 70 degrees or more.

17. The semiconductor device of claim 4, wherein
in each of the plurality of semiconductor portions, an interior angle formed between a surface, intersecting with the first direction, of the second nitride semiconductor portion and a surface, parallel to the first surface, of one of the plurality of second electrodes that is directly electrically connected to the heterojunction of the associated semiconductor portion is 70 degrees or more.

18. The semiconductor device of claim 10, wherein
in each of the plurality of semiconductor portions, an interior angle formed between a surface, intersecting with the first direction, of the second nitride semiconductor portion and a surface, parallel to the first surface of the nitride semiconductor substrate, of one of the plurality of insulator portions that is in contact with the second nitride semiconductor portion is 70 degrees or more.

19. The semiconductor device of claim 10, further comprising a plurality of gate electrodes, each of the plurality of gate electrodes facing, in the first direction, the second nitride semiconductor portion of an associated one of the plurality of semiconductor portions.

20. The semiconductor device of claim 11, further comprising a plurality of gate electrodes, each of the plurality of gate electrodes facing, in the first direction, the second nitride semiconductor portion of an associated one of the plurality of semiconductor portions.
